(19) United States
(12) Patent Application Publication
(10) Pub. No.: US 2008/0272448 A1
(43) Pub. Date: Nov. 6, 2008

(54) INTEGRATED CIRCUIT HAVING A MAGNETIC TUNNEL JUNCTION DEVICE

(76) Inventor: Faiz Dahmani, La Varenne Saint-Hilaire (FR)

Correspondence Address: Steven E. Dicke;Dicke, Billig & Czaja, PLLC, Suite 2250, 100 South 5th Street, Minneapolis, MN, 55402, US

(21) Appl. No.: 11/743,488

(22) Filed: May 2, 2007

(51) Int. Cl. H01L 29/82; G11C 11/02; H01L 21/00

(52) U.S. Cl. 257/421; 365/173; 438/3; 257/E29.323; 257/E21.001

(57) ABSTRACT

An integrated circuit having a magnetic tunnel junction device is disclosed. In one embodiment, the device includes: a spin transfer torque magnetization reversal structure including a first ferromagnetic structure, a second ferromagnetic structure, and a tunnel barrier structure between the first ferromagnetic structure and the second ferromagnetic structure.

### BACKGROUND

Magnetic (or magneto-resistive) random access memory (MRAM) is a non-volatile memory technology that shows considerable promise for long-term data storage. Performing read and write operations on MRAM devices is much faster than performing read and write operations on conventional memory devices such as DRAM and Flash and order of magnitude faster than long-term storage device such as hard drives.

In MRAM devices, the information is no longer stored by electrical charges, as in semiconductor memories, but by two opposite directions of the magnetization vectors in a small magnetic structure. Conventionally, the basic MRAM cell is the so-called magnetic tunnel junction (MTJ) which consists of multiple ferromagnetic layers sandwiching at least one non-magnetic layer. The information is stored as directions of magnetization vectors in the magnetic layers. The magnetization of one of the layers, acting as a reference layer, is fixed or pinned and kept rigid in one given direction. The other layer, acting as the storage layer is free to switch between the same and opposite directions that are called parallel and anti-parallel states, respectively. The corresponding logic state (“0” or “1”) of the memory is hence defined by its resistance state (low or high). The change in conductance for these two magnetic states is described as a magneto-resistance. Accordingly, a detection of change in resistance allows an MRAM device to provide information stored in the magnetic memory element. The difference between the maximum (anti-parallel; R_{AP}) and minimum (parallel; R_{P}) resistance values, divided by the minimum resistance is known as the tunneling magnetoresistance ratio (TMR) of the magnetic tunnel junction (MTJ) and is defined as (R_{AP}−R_{P})/R_{P}.

A fully functional MRAM memory is based on a 2D array of individual cells, which can be addressed individually. Conventional architecture combines a CMOS selection transistor, a magnetic tunnel junction, and two line levels called “bit lines” and “word lines”. At read, a low power current pulse opens the transistor to address the selected memory cell. The cell resistance is measured by driving a current from the “word line” through the MTJ and comparing it to a reference cell located somewhere in the array. At write, the “word lines” and “bit lines”, arranged in cross-point architecture on each side of the magnetic tunnel junction (MTJ), are energized by synchronized current pulses generating a magnetic field on the addressed memory cell. The intensities of these current pulses are such that only the storage or free layer at the cross-point of the two lines (the so-called fully selected cell) is switched, all other cells on any given line or column (the so-called half selected cells) being unable to switch. This concept is the so-called field induced magnetization switching (FIMS). Scaling down memory cells to below 100-nm, the field induced magnetization switching (FIMS) concept may reach its limits for the following reasons: (i) the write power may increase, due to the switching field being inversely proportional to particle size, (ii) the selection errors at write may increase, as the switching field distribution is expected to broaden for these reduced dimensions, (iii) the long-term stability of the data may be negatively impacted, due to increasing effect of thermal activation.

In order to scale cell size and decrease write currents, future generations of MRAM may use spin transfer (or torque) as the write mechanism. An applied vertical current gets spin polarized when it passes through a tunneling barrier and causes a torque on the magnetic polarization of the free layer, which torque can be large enough to induce a complete reversal of the magnetization. One of the major benefits of such a concept is the enormous potential for very small cell size as the material thermal stability limit requirements are in this case independent of the current-induced switching parameters. However, the typical current density required to induce switching is so high (e.g.: 10⁶-10⁷ A/cm2) that the magnetic tunnel junction (MTJ) may be damaged.

Therefore, it is important to develop magnetic tunnel junction (MTJ) devices characterized by high tunneling magnetoresistance ratios (e.g.: TMR>100%), very low resistance-area values (e.g.: RA<10 Ω-μm²) and high breakdown voltage (e.g.: V_{BD}˜0.6 V) for current-induced magnetization switching (CIMS).

For these and other reasons, there is a need for the present invention.

### SUMMARY

One or more embodiments provide an integrated circuit having a magnetic tunnel junction device. In one embodiment, the device includes: a spin transfer torque magnetization reversal structure including a first ferromagnetic structure, a second ferromagnetic structure, and a tunnel barrier structure between the first ferromagnetic structure and the second ferromagnetic structure.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated, as they become better understood by reference to the following detailed description. The elements of the drawings are not necessarily to scale relative to each other. Like reference numerals designate corresponding similar parts.

FIG. 1 is a cross-sectional view of illustrating one embodiment of an integrated circuit having a magnetic tunnel junction.

FIG. 2 is a cross-sectional view of a magnetic tunnel junction according one embodiment.

FIG. 3 is a cross-sectional view illustrating one embodiment of a magnetic tunnel junction.

FIG. 4 is a cross-sectional view illustrating one embodiment of a magnetic tunnel junction.

FIG. 5 is a cross-sectional view illustrating one embodiment of a magnetic tunnel junction according to one embodiment.

FIG. 6 is a cross-sectional view illustrating one embodiment of a magnetic tunnel junction according to one embodiment.

FIG. 7a is a graph illustrating examples of the tunneling magnetoresistance (TMR) of a magnetic tunnel junction device as a function of different tunnel barrier types according to different embodiments.

FIG. 7b is a graph illustrating examples of the resistance-area values (RA) of a magnetic tunnel junction device as a function of different tunnel barrier types according to different embodiments.

FIG. 8 is a graph illustrating examples of the tunneling magnetoresistance (TMR) and the resistance-area values (RA) of a magnetic tunnel junction device as a function of different reference layer structures according to different embodiments.

FIG. 9 is a graph illustrating examples of the breakdown voltage values of a magnetic tunnel junction device as a function of different area junctions for different resistance-area (RA) values according to different embodiments.

FIGS. 10A and 10B illustrate examples of memory devices employing magnetic tunnel junction devices according to some embodiments.

FIG. 11 illustrates an example of a computing system employing magnetic tunnel junction devices according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

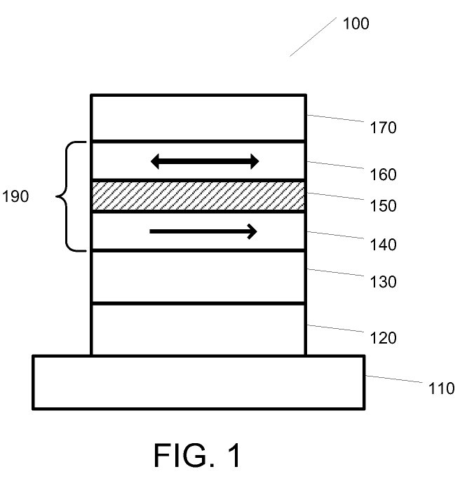

FIG. 1 illustrates a cross-sectional view of one embodiment of an integrated circuit having a magnetic tunnel junction, (MTJ). In one embodiment, the magnetic tunnel junction stack 100 includes a carrier 110 (e.g. a substrate), followed by the formation of a bottom conducting layer structure 120 (also referred to as “bottom lead layer”) on or above the carrier 110. In one embodiment, the conducting bottom layer structure 120 may be a multilayer formation of a Tantalum Nitride (TaN) layer and a Tantalum (Ta) layer deposited by sputter processes according to the sequence TaN—Ta (Ta layer formed above or on the TaN layer). In one embodiment, the Tantalum Nitride (TaN) layer may have an approximate thickness of two to six nanometers, while the Tantalum (Ta) layer may have an approximate thickness of one to three nanometers, although these ranges should be considered approximations and reasonable variations, due for example to manufacturing, can and should be expected.

In one embodiment, a bottom pinning layer structure of antiferromagnetic material (AFM) 130 is formed on or above the bottom conducting layer structure 120. In one embodiment, the pinning layer structure of antiferromagnetic material 130 may be a Platinum Manganese (PtMn) layer. In one embodiment, the pinning layer structure of antiferromagnetic material 130 may be an Iridium Manganese (IrMn) layer.

In one embodiment, a first ferromagnetic layer structure 140 is formed on or above the bottom pinning layer structure of antiferromagnetic material 130. In one embodiment, the first ferromagnetic layer structure 140 may comprise at least two components of alloys of Cobalt (Co), Iron (Fe), and Nickel (Ni). In one embodiment, the first ferromagnetic layer structure 140 may be made amorphous by doping the alloys with Boron (B). In one embodiment, the first ferromagnetic layer structure 140, acting as a “reference layer”, is pinned to the pinning layer structure of antiferromagnetic material 130, in that its magnetic moment is prevented from any rotation in the presence of an external applied magnetic field up to a certain strength value.

In one embodiment, a tunnel barrier layer structure 150 is formed on or above the first ferromagnetic layer structure 140. In one embodiment, the tunnel barrier layer structure 150 may comprise Magnesium Oxide (MgO). In one embodiment, the tunnel barrier layer structure 150 may comprise Aluminium Oxide (Al₂O₃).

In one embodiment, a second ferromagnetic layer structure 160 (also referred to as “free layer”) is formed on or above the tunnel barrier layer structure 150. In one embodiment, the second ferromagnetic layer structure 160 may comprise at least two components of alloys of Cobalt (Co), Iron (Fe), and Nickel (Ni). In one embodiment, the second ferromagnetic layer structure 160 may be made amorphous by doping the alloys with Boron (B). In one embodiment, the second ferromagnetic layer structure 160, acting as a storage layer, is not pinned and is free to rotate in the presence of a sufficient applied magnetic field.

In one embodiment, the first ferromagnetic layer structure 140 together with the tunnel barrier layer structure 150 and the second ferromagnetic layer structure 160 form a spin transfer torque magnetization reversal layer structure 190. In one embodiment, during a write operation, a vertical current applied to the device and passing through the spin transfer torque magnetization reversal layer structure 190 (i.e. through the second ferromagnetic layer structure 160, the tunnel barrier layer structure 150 and the first ferromagnetic layer structure 140) gets spin polarized and causes a torque on the magnetic polarization of the second ferromagnetic layer structure 160. In one embodiment, this torque is large enough to induce a complete reversal of the magnetization of the second ferromagnetic layer structure 160 such that the second ferromagnetic layer structure 160 functions as a storage layer to store information. In one embodiment, a top conductive layer structure 170 is formed on or above the second ferromagnetic layer structure 160.

In one embodiment, the top conducting layer structure 170 may be a multilayer formation of a Tantalum (Ta) layer and a Tantalum Nitride (TaN) layer formed on or above the Tantalum (Ta) layer. In one embodiment, the Tantalum (Ta) layer may have an approximate thickness of 2 to 10 nanometers, while the Tantalum Nitride (TaN) layer may have an approximate thickness of 5 to 10 nanometers, although these ranges should be considered approximations and reasonable variations, due for example to manufacturing, can and should be expected.

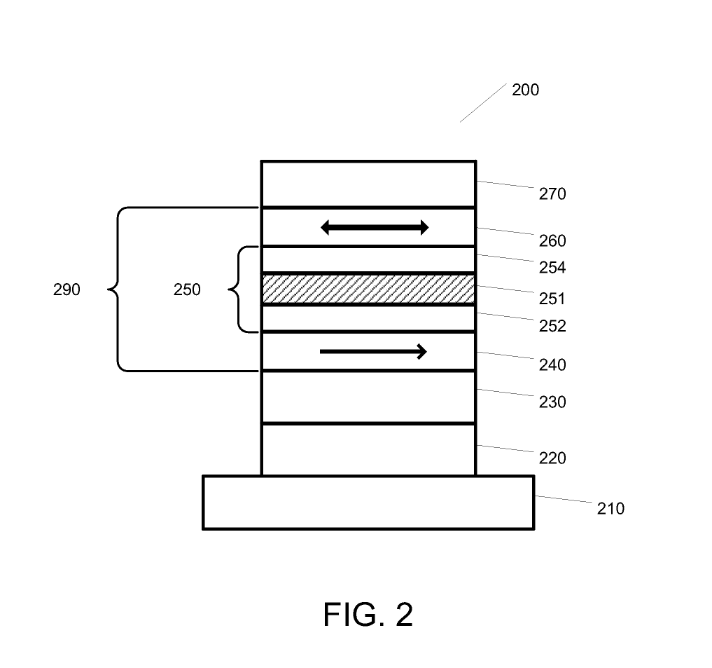

FIG. 2 is a cross-sectional view of one embodiment of a magnetic tunnel junction. In one embodiment, the magnetic tunnel junction (MTJ) stack 200 includes a carrier 210 (e.g. a substrate), followed by the formation of a bottom conducting layer structure 220 (also referred to as “bottom lead layer”) on or above the carrier 210. In one embodiment, the conducting bottom layer structure 220 may be a multilayer formation of a Tantalum Nitride (TaN) layer and a Tantalum (Ta) layer deposited by sputter processes according to the sequence TaN—Ta (Ta layer formed above or on the TaN layer). In one embodiment, the Tantalum Nitride (TaN) layer may have an approximate thickness of two to six nanometers, while the Tantalum (Ta) layer may have an approximate thickness of one to three nanometers, although these ranges should be considered approximations and reasonable variations, due for example to manufacturing, can and should be expected.

In one embodiment, a bottom pinning layer structure of antiferromagnetic material (AFM) 230 is formed on or above the bottom conducting layer structure 220. In one embodiment, the pinning layer structure of antiferromagnetic material 230 may be a Platinum Manganese (PtMn) layer. In one embodiment, the pinning layer structure of antiferromagnetic material 230 may be an Iridium Manganese (IrMn) layer.

In one embodiment, a first ferromagnetic layer structure 240 is formed on or above the bottom pinning layer structure of antiferromagnetic material 230. In one embodiment, the first ferromagnetic layer structure 240 may comprise at least two components of alloys of Cobalt (Co), Iron (Fe), and Nickel (Ni). In one embodiment, the first ferromagnetic layer structure 240 may be made amorphous by doping the alloys with Boron (B). In one embodiment, the first ferromagnetic layer structure 240, acting as a “reference layer”, is pinned to the bottom pinning layer structure of antiferromagnetic material 230, in that its magnetic moment is prevented from any rotation in the presence of an external applied magnetic field up to a certain strength value.

In one embodiment, a tunnel barrier layer structure 250 is formed on or above the first ferromagnetic layer structure 240. In one embodiment, the tunnel barrier layer structure 250 is a multilayer formation comprising a first metallic layer 252, a central tunnel barrier layer 251 formed on or above the first metallic layer 252, and a second metallic layer 254 formed on or above central tunnel barrier layer 251. In one embodiment, the first metallic 252 layer of the tunnel barrier layer structure 250 is a Magnesium (Mg) layer.

In one embodiment, the first metallic layer 252 of Magnesium (Mg) has an approximate thickness of 1 to 3.9 Angstroms (Å), although these ranges should be considered approximations and reasonable variations, due for example to manufacturing, can and should be expected. In one embodiment, the first metallic layer 252 of Magnesium (Mg) has an approximate thickness of 2 Angstroms (Å). In one embodiment, the central tunnel barrier layer 251 of the tunnel barrier layer structure 250 is a Magnesium Oxide (MgO) layer. In one embodiment, the central tunnel barrier layer 251 of Magnesium Oxide (MgO) is formed by RF-sputtering from a Magnesium Oxide (MgO) target. In one embodiment, the central tunnel barrier layer 251 of Magnesium Oxide (MgO) is formed by radical oxidation of a pre-sputtered metallic layer of Magnesium (e.g. reactively depositing additional metallic Magnesium in the presence of Oxygen, in-situ radical, natural or plasma oxidation). In one embodiment, the second metallic layer 254 of the tunnel barrier layer structure 250 is a Magnesium (Mg) layer. In one embodiment, the second metallic layer 254 of Magnesium (Mg) has an approximate thickness of 1 to 3.9 Angstroms (Å), although these ranges should be considered approximations and reasonable variations, due for example to manufacturing, can and should be expected. In one embodiment, the second metallic layer 254 of Magnesium (Mg) has an approximate thickness of 2 Angstroms (Å).

In one embodiment, the first metallic 252 layer of the tunnel barrier layer structure 250 is an Aluminium (Al) layer. In one embodiment, the first metallic layer 252 of Aluminium (Al) has an approximate thickness of 1 to 3.9 Angstroms (Å), although these ranges should be considered approximations and reasonable variations, due for example to manufacturing, can and should be expected. In one embodiment, the first metallic layer 252 of Aluminium (Al) has an approximate thickness of 2 Angstroms (Å). In one embodiment, the central tunnel barrier layer 251 of the tunnel barrier layer structure 250 is an Aluminium Oxide (Al₂O₃) layer. In one embodiment, the central tunnel barrier layer 251 of Aluminium Oxide (Al₂O₃) is formed by RF-sputtering from an Aluminium Oxide (Al₂O₃) target. In one embodiment, the central tunnel barrier layer 251 of Aluminium Oxide (Al₂O₃) is formed by radical oxidation of a pre-sputtered metallic layer of Aluminium (e.g. depositing an additional metallic Aluminium layer followed by in-situ radical, natural or plasma oxidation). In one embodiment, the second metallic layer 254 of the tunnel barrier layer structure 250 is an Aluminium (Al) layer. In one embodiment, the second metallic layer 254 of Aluminium (Al) has an approximate thickness of 1 to 3.9 Angstroms (Å). In one embodiment, the second metallic layer 254 of Aluminium (Al) has an approximate thickness of 2 Angstroms (Å). These ranges, however, should be considered approximations and reasonable variations, due for example to manufacturing, can and should be expected.

In other embodiments, this method of fabricating the tunnel barrier layer structure 250 may be extended to other materials than MgO or Al₂O₃. In one embodiment, the introduction of the first metallic layer 252 and the second metallic layer 254 in the tunnel barrier layer structure 250 and, in particular, the use of the same material for these two metallic layers improves the bottom and top interface of the central tunnel barrier layer 251 generating a high quality tunnel barrier layer structure 250. This method of fabricating the tunnel barrier layer structure 250, enables high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching to be obtained.

In one embodiment, a second ferromagnetic layer structure 260 (also referred to as “free layer”) is formed on or above the tunnel barrier layer structure 250. In one embodiment, second ferromagnetic layer structure 260 may comprise at least two components of alloys of Cobalt (Co), Iron (Fe), and Nickel (Ni). In one embodiment, the second ferromagnetic layer structure 260 may be made amorphous by doping the alloys with Boron (B). In one embodiment, the second ferromagnetic layer structure 260, acting as a storage layer, is not pinned and is free to rotate in the presence of a sufficient applied magnetic field.

In one embodiment, the first ferromagnetic layer structure 240 together with the tunnel barrier layer structure 250 and the second ferromagnetic layer structure 260 form a spin transfer torque magnetization reversal layer structure 290. In one embodiment, during a write operation, a vertical current applied to the device and passing through the spin transfer torque magnetization reversal layer structure 290 (i.e. through the second ferromagnetic layer structure 260, the tunnel barrier layer structure 250 and the first ferromagnetic layer structure 240) gets spin polarized and causes a torque on the magnetic polarization of the second ferromagnetic layer structure 260. In one embodiment, this torque is large enough to induce a complete reversal of the magnetization of the second ferromagnetic layer structure 260 such that the second ferromagnetic layer structure 260 functions as a storage layer to store information.

In one embodiment, a top conductive layer structure 270 is formed on or above the second ferromagnetic layer structure 260. In one embodiment, the top conducting layer structure 270 may be a multilayer formation of a Tantalum (Ta) layer and a Tantalum Nitride (TaN) layer formed on or above the Tantalum (Ta) layer. In one embodiment, the Tantalum (Ta) layer may have an approximate thickness of 2 to 10 nanometers, while the Tantalum Nitride (TaN) layer may have an approximate thickness of 5 to 10 nanometers, although these ranges should be considered approximations and reasonable variations, due for example to manufacturing, can and should be expected.

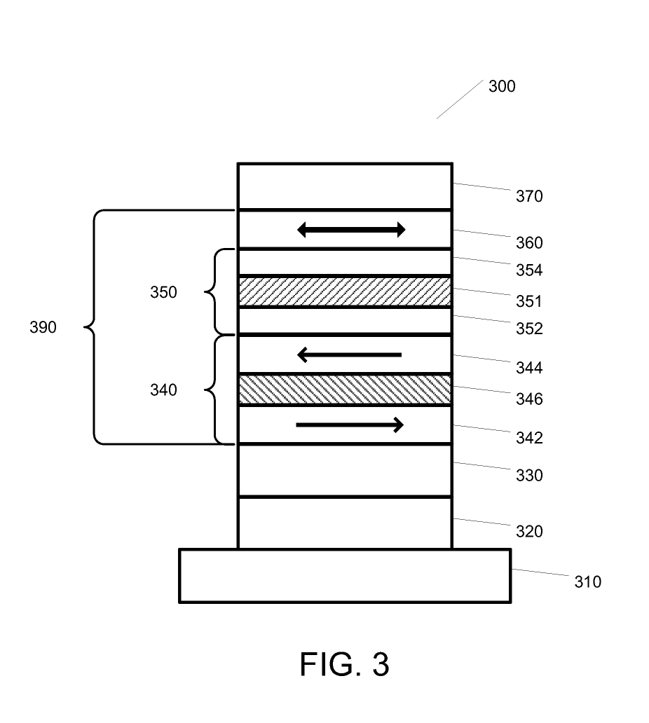

FIG. 3 is a cross-sectional view of one embodiment of a magnetic tunnel junction. In one embodiment, the magnetic tunnel junction (MTJ) stack 300 includes a carrier 310 (e.g. a substrate), followed by the formation of a bottom conducting layer structure 320 (also referred to as “bottom lead layer”) on or above the carrier 310. In one embodiment, the conducting bottom layer structure 320 may be a multilayer formation of a Tantalum Nitride (TaN) layer and a Tantalum (Ta) layer deposited by sputter processes according to the sequence TaN—Ta (Ta layer formed above or on the TaN layer). In one embodiment, the Tantalum Nitride (TaN) layer may have an approximate thickness of two to six nanometers, while the Tantalum (Ta) layer may have an approximate thickness of one to three nanometers, although these ranges should be considered approximations and reasonable variations, due for example to manufacturing, can and should be expected.

In one embodiment, a bottom pinning layer structure of antiferromagnetic material (AFM) 330 is formed on or above the bottom conducting layer structure 320. In one embodiment, the pinning layer structure of antiferromagnetic material 330 may be a Platinum Manganese (PtMn) layer. In one embodiment, the pinning layer structure of antiferromagnetic material 330 may be an Iridium Manganese (IrMn) layer.

In one embodiment, a first ferromagnetic layer structure 340, acting as a “reference layer”, is formed on or above the bottom pinning layer structure of antiferromagnetic material 330. In one embodiment, the first ferromagnetic layer structure 340 is a multilayer formation comprising a third ferromagnetic layer structure 342 disposed on or above the bottom pinning layer structure 330 of antiferromagnetic material, an antiferromagnetic coupling layer structure 346 disposed on or above the third ferromagnetic layer structure 342 and a fourth ferromagnetic layer structure 344 disposed on or above an antiferromagnetic coupling layer structure 346.

In one embodiment, the third ferromagnetic layer structure 342 is pinned to the bottom pinning layer structure of antiferromagnetic material 330, in that its magnetic moment is prevented from any rotation in the presence of an external applied magnetic field up to a certain strength value. In one embodiment, the third ferromagnetic layer structure 342 and the fourth ferromagnetic layer structure 344 are magnetized in antiparallel directions with respect to each other (e.g. anti-ferromagnetically exchanged coupled with each other) through the antiferromagnetic coupling layer structure 346, in that their magnetic moment is prevented from any rotation in the presence of an external applied magnetic field up to a certain strength value.

In one embodiment, the third ferromagnetic layer structure 342 comprises (at least two) components of alloys of Cobalt (Co), Iron (Fe), and Nickel (Ni). In one embodiment, the third ferromagnetic layer structure 342 may be made amorphous by doping the alloys with Boron (B). In one embodiment, the antiferromagnetic coupling layer structure 346 comprises a Ruthenium (Ru) layer. In one embodiment, the antiferromagnetic coupling layer structure 346 has an approximate thickness of 8.1 Angstroms (Å) to 8.9 Angstroms (Å), although these ranges should be considered approximations and reasonable variations, due for example to manufacturing, can and should be expected. In one embodiment, the fourth ferromagnetic layer structure 344 comprises (at least two) components of alloys of Cobalt (Co), Iron (Fe), and Nickel (Ni). In one embodiment, the fourth ferromagnetic layer structure 344 may be made amorphous by doping the alloys with Boron (B).

In one embodiment, a tunnel barrier layer structure 350 is formed on or above the first ferromagnetic layer structure 340. In one embodiment, the tunnel barrier layer structure 350 is a multilayer formation comprising a first metallic layer 352, a central tunnel barrier layer 351 formed on or above the first metallic layer 352, and a second metallic layer 354 formed on or above central tunnel barrier layer 351.

In one embodiment, the first metallic 352 layer of the tunnel barrier layer structure 350 is a Magnesium (Mg) layer. In one embodiment, the first metallic layer 352 of Magnesium (Mg) has an approximate thickness of 1 to 3.9 Angstroms (Å), although these ranges should be considered approximations and reasonable variations, due for example to manufacturing, can and should be expected. In one embodiment, the first metallic layer 352 of Magnesium (Mg) has an approximate thickness of 2 Angstroms (Å). In one embodiment, the central tunnel barrier layer 351 of the tunnel barrier layer structure 350 is a Magnesium Oxide (MgO) layer. In one embodiment, the central tunnel barrier layer 351 of Magnesium Oxide (MgO) is formed by RF-sputtering from a Magnesium Oxide (MgO) target. In one embodiment, the central tunnel barrier layer 351 of Magnesium Oxide (MgO) is formed by radical oxidation of a pre-sputtered metallic layer of Magnesium (e.g. reactively depositing additional metallic Magnesium in the presence of Oxygen, in-situ radical, natural or plasma oxidation). In one embodiment, the second metallic layer 354 of the tunnel barrier layer structure 350 is a Magnesium (Mg) layer. In one embodiment, the second metallic layer 354 of Magnesium (Mg) has an approximate thickness of 1 to 3.9 Angstroms (Å), although these ranges should be considered approximations and reasonable variations, due for example to manufacturing, can and should be expected. In one embodiment, the second metallic layer 354 of Magnesium (Mg) has an approximate thickness of 2 Angstroms (Å).

In one embodiment, the first metallic 352 layer of the tunnel barrier layer structure 350 is an Aluminium (Al) layer. In one embodiment, the first metallic layer 352 of Aluminium (Al) has an approximate thickness of 1 to 3.9 Angstroms (Å), although these ranges should be considered approximations and reasonable variations, due for example to manufacturing, can and should be expected. In one embodiment, the first metallic layer 352 of Aluminium (Al) has an approximate thickness of 2 Angstroms (Å). In one embodiment, the central tunnel barrier layer 351 of the tunnel barrier layer structure 350 is an Aluminium Oxide (Al₂O₃) layer. In one embodiment, the central tunnel barrier layer 351 of Aluminium Oxide (Al₂O₃) is formed by RF-sputtering from an Aluminium Oxide (Al₂O₃) target. In one embodiment, the central tunnel barrier layer 351 of Aluminium Oxide (Al₂O₃) is formed by radical oxidation of a pre-sputtered metallic layer of Aluminium (e.g. depositing an additional metallic Aluminium layer followed by in-situ radical, natural or plasma oxidation). In one embodiment, the second metallic layer 354 of the tunnel barrier layer structure 350 is an Aluminium (Al) layer. In one embodiment, the second metallic layer 354 of Aluminium (Al) has an approximate thickness of 1 to 3.9 Angstroms (Å). In one embodiment, the second metallic layer 354 of Aluminium (Al) has an approximate thickness of 2 Angstroms (Å). These ranges, however, should be considered approximations and reasonable variations, due for example to manufacturing, can and should be expected.

In other embodiments, this method of fabricating the tunnel barrier layer structure 350 may be extended to other materials than MgO or Al₂O₃. In one embodiment, the introduction of the first metallic layer 352 and the second metallic layer 354 in the tunnel barrier layer structure 350 and, in particular, the use of the same material for these two metallic layers improves the bottom and top interface of the central tunnel barrier layer 351 generating a high quality tunnel barrier layer structure 350. This method of fabricating the tunnel barrier layer structure 350, enables high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching to be obtained.

In one embodiment, a second ferromagnetic layer structure 360 (also referred to as “free layer”) is formed on or above the tunnel barrier layer structure 350. In one embodiment, second ferromagnetic layer structure 360 may comprise at least two components of alloys of Cobalt (Co), Iron (Fe), and Nickel (Ni). In one embodiment, the second ferromagnetic layer structure 360 may be made amorphous by doping the alloys with Boron (B). In one embodiment, the second ferromagnetic layer structure 360, acting as a storage layer, is not pinned and is free to rotate in the presence of a sufficient applied magnetic field.

In one embodiment, the first ferromagnetic layer structure 340 together with the tunnel barrier layer structure 350 and the second ferromagnetic layer structure 360 form a spin transfer torque magnetization reversal layer structure 390. In one embodiment, during a write operation, a vertical current applied to the device and passing through the spin transfer torque magnetization reversal layer structure 390 (i.e. through the second ferromagnetic layer structure 360, the tunnel barrier layer structure 350 and the first ferromagnetic layer structure 340) gets spin polarized and causes a torque on the magnetic polarization of the second ferromagnetic layer structure 360. In one embodiment, this torque is large enough to induce a complete reversal of the magnetization of the second ferromagnetic layer structure 360 such that the second ferromagnetic layer structure 360 functions as a storage layer to store information.

In one embodiment, a top conductive layer structure 370 is formed on or above the second ferromagnetic layer structure 360. In one embodiment, the top conducting layer structure 370 may be a multilayer formation of a Tantalum (Ta) layer and a Tantalum Nitride (TaN) layer formed on or above the Tantalum (Ta) layer. In one embodiment, the Tantalum (Ta) layer may have an approximate thickness of 2 to 10 nanometers, while the Tantalum Nitride (TaN) layer may have an approximate thickness of 5 to 10 nanometers, although these ranges should be considered approximations and reasonable variations, due for example to manufacturing, can and should be expected.

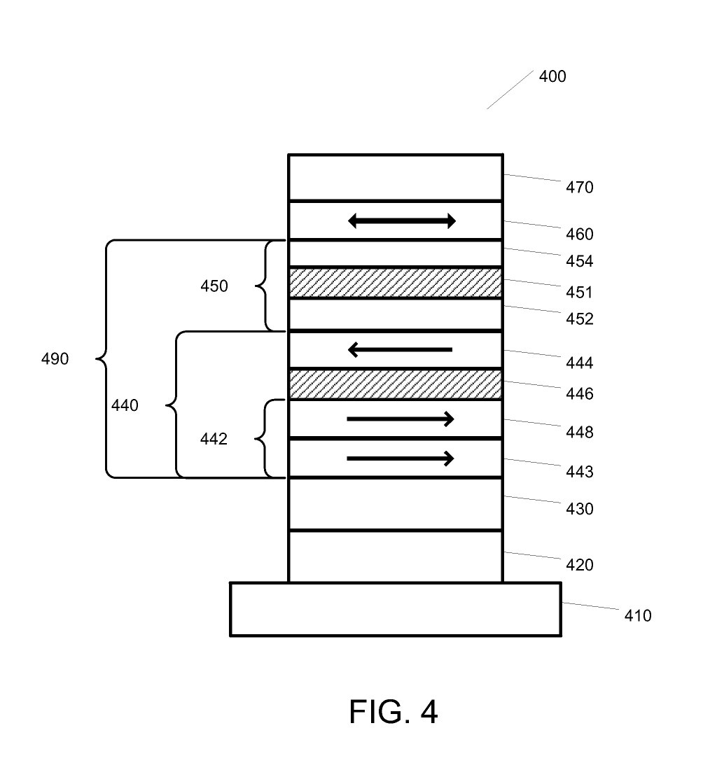

FIG. 4 is a cross-sectional view of one embodiment of a magnetic tunnel junction. In one embodiment, the magnetic tunnel junction (MTJ) stack 400 includes a carrier 410 (e.g. a substrate), followed by the formation of a bottom conducting layer structure 420 (also referred to as “bottom lead layer”) on or above the carrier 410. In one embodiment, the conducting bottom layer structure 420 may be a multilayer formation of a Tantalum Nitride (TaN) layer and a Tantalum (Ta) layer deposited by sputter processes according to the sequence TaN—Ta (Ta layer formed above or on the TaN layer). In one embodiment, the Tantalum Nitride (TaN) layer may have an approximate thickness of two to six nanometers, while the Tantalum (Ta) layer may have an approximate thickness of one to three nanometers, although these ranges should be considered approximations and reasonable variations, due for example to manufacturing, can and should be expected.

In one embodiment, a bottom pinning layer structure of antiferromagnetic material (AFM) 430 is formed on or above the bottom conducting layer structure 420. In one embodiment, the pinning layer structure of antiferromagnetic material 430 may be a Platinum Manganese (PtMn) layer. In one embodiment, the pinning layer structure of antiferromagnetic material 430 may be an Iridium Manganese (IrMn) layer.

In one embodiment, a first ferromagnetic layer structure 440, acting as a “reference layer”, is formed on or above the bottom pinning layer structure of antiferromagnetic material 430. In one embodiment, the first ferromagnetic layer structure 440 is a multilayer formation comprising a third ferromagnetic layer structure 442 disposed on or above the bottom pinning layer structure 430 of antiferromagnetic material, an antiferromagnetic coupling layer structure 446 disposed on or above the third ferromagnetic layer structure 442, and a fourth ferromagnetic layer structure 444 disposed on or above the antiferromagnetic coupling layer structure 446.

In one embodiment, the third ferromagnetic layer structure 442 is a multilayer formation comprising a fifth ferromagnetic layer structure 443 disposed on or above the bottom pinning layer structure 430 of antiferromagnetic material and a sixth ferromagnetic layer structure 448 disposed on or above the fifth ferromagnetic layer structure 443. In one embodiment, the fifth ferromagnetic layer structure 443 and the sixth ferromagnetic layer structure 448 are both pinned to the bottom pinning layer structure of antiferromagnetic material 430, in that their magnetic moments are prevented from any rotation in the presence of an external applied magnetic field up to a certain strength value. In one embodiment, the fifth ferromagnetic layer structure 443 and the sixth ferromagnetic layer structure 448 are both anti-ferromagnetically exchanged coupled to the fourth ferromagnetic layer structure 444 through the antiferromagnetic coupling layer structure 446.

In one embodiment, the fifth ferromagnetic layer structure 443 comprises at least two elements selected from the group of alloys Cobalt (Co), Iron (Fe), and Nickel (Ni). In one embodiment, the fifth ferromagnetic layer structure 443 has an approximate thickness of 1 Angstrom (Å) to 30 Angstroms (Å). These ranges, however, should be considered approximations and reasonable variations, due for example to manufacturing, can and should be expected.

In one embodiment, the sixth ferromagnetic layer structure 448 is an amorphous magnetic layer comprising a Cobalt Iron Boron (CoFeB) layer. In one embodiment, the sixth ferromagnetic layer structure 448 of Cobalt Iron Boron (CoFeB) has an approximate atom percentage of Boron (B) of 2% to 20%. In one embodiment, the sixth ferromagnetic layer structure 448 of Cobalt Iron Boron (CoFeB) has an approximate atom percentage of Boron (B) of 8% to 13%. In one embodiment, the sixth ferromagnetic layer structure 448 of Cobalt Iron Boron (CoFeB) has an approximate atom percentage of Boron (B) of 13%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously. In one embodiment, the sixth ferromagnetic layer structure 448 of Cobalt Iron Boron (CoFeB) has an approximate thickness of one Angstrom (Å) to 30 Angstroms (Å). In one embodiment, the sixth ferromagnetic layer structure 448 of Cobalt Iron Boron (CoFeB) has an approximate thickness of 3 Angstroms (Å). These ranges, however, should be considered approximations and reasonable variations, due for example to manufacturing, can and should be expected.

Using this method of fabricating the third ferromagnetic layer structure 442, it is possible to obtain high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching.

In one embodiment, the antiferromagnetic coupling layer structure 446 comprises a Ruthenium (Ru) layer. In one embodiment, the antiferromagnetic coupling layer structure 446 has an approximate thickness of 8.1 Angstroms (Å) to 8.9 Angstroms (Å), although these ranges should be considered approximations and reasonable variations, due for example to manufacturing, can and should be expected. In one embodiment, the fourth ferromagnetic layer structure 444 comprises (at least two) components of alloys of Cobalt (Co), Iron (Fe), and Nickel (Ni). In one embodiment, the fourth ferromagnetic layer structure 444 may be made amorphous by doping the alloys with Boron (B).

In one embodiment, a tunnel barrier layer structure 450 is formed on or above the first ferromagnetic layer structure 440. In one embodiment, the tunnel barrier layer structure 450 is a multilayer formation comprising a first metallic layer 452, a central tunnel barrier layer 451 formed on or above the first metallic layer 452, and a second metallic layer 454 formed on or above central tunnel barrier layer 451.

In one embodiment, the first metallic 452 layer of the tunnel barrier layer structure 450 is a Magnesium (Mg) layer. In one embodiment, the first metallic layer 452 of Magnesium (Mg) has an approximate thickness of 1 to 3.9 Angstroms (Å). In one embodiment, the first metallic layer 452 of Magnesium (Mg) has an approximate thickness of 2 Angstroms (Å). These ranges, however, should be considered approximations and reasonable variations, due for example to manufacturing, can and should be expected. In one embodiment, the central tunnel barrier layer 451 of the tunnel barrier layer structure 450 is a Magnesium Oxide (MgO) layer. In one embodiment, the central tunnel barrier layer 451 of Magnesium Oxide (MgO) is formed by RF-sputtering from a Magnesium Oxide (MgO) target. In one embodiment, the central tunnel barrier layer 451 of Magnesium Oxide (MgO) is formed by radical oxidation of a pre-sputtered metallic layer of Magnesium (e.g. reactively depositing additional metallic Magnesium in the presence of Oxygen, in-situ radical, natural or plasma oxidation). In one embodiment, the second metallic layer 454 of the tunnel barrier layer structure 450 is a Magnesium (Mg) layer. In one embodiment, the second metallic layer 454 of Magnesium (Mg) has an approximate thickness of 1 to 3.9 Angstroms (Å), although these ranges should be considered approximations and reasonable variations, due for example to manufacturing, can and should be expected. In one embodiment, the second metallic layer 454 of Magnesium (Mg) has an approximate thickness of 2 Angstroms (Å). These ranges, however, should be considered approximations and reasonable variations, due for example to manufacturing, can and should be expected.

In one embodiment, the first metallic 452 layer of the tunnel barrier layer structure 450 is an Aluminium (Al) layer. In one embodiment, the first metallic layer 452 of Aluminium (Al) has an approximate thickness of 1 to 3.9 Angstroms (Å), although these ranges should be considered approximations and reasonable variations, due for example to manufacturing, can and should be expected. In one embodiment, the first metallic layer 452 of Aluminium (Al) has an approximate thickness of 2 Angstroms (Å). In one embodiment, the central tunnel barrier layer 451 of the tunnel barrier layer structure 450 is an Aluminium Oxide (Al₂O₃) layer. In one embodiment, the central tunnel barrier layer 451 of Aluminium Oxide (Al₂O₃) is formed by RF-sputtering from an Aluminium Oxide (Al₂O₃) target. In one embodiment, the central tunnel barrier layer 451 of Aluminium Oxide (Al₂O₃) is formed by radical oxidation of a pre-sputtered metallic layer of Aluminium (e.g. depositing an additional metallic Aluminium layer followed by in-situ radical, natural or plasma oxidation). In one embodiment, the second metallic layer 454 of the tunnel barrier layer structure 450 is an Aluminium (Al) layer. In one embodiment, the second metallic layer 454 of Aluminium (Al) has an approximate thickness of 1 to 3.9 Angstroms (Å). In one embodiment, the second metallic layer 454 of Aluminium (Al) has an approximate thickness of 2 Angstroms (Å). These ranges, however, should be considered approximations and reasonable variations, due for example to manufacturing, can and should be expected.

In other embodiments, this method of fabricating the tunnel barrier layer structure 450 may be extended to other materials than MgO or Al₂O₃. In one embodiment, the introduction of the first metallic layer 452 and the second metallic layer 454 in the tunnel barrier layer structure 450 and, in particular, the use of the same material for these two metallic layers improves the bottom and top interface of the central tunnel barrier layer 451 generating a high quality tunnel barrier layer structure 450. This method of fabricating the tunnel barrier layer structure 450 enables high tunneling magnetoresistance ratios (e.g.: TMR>100%), very low resistance-area values (e.g.: RA<10 Ω-μm²) and high breakdown voltage (e.g.: V_{BD}˜0.6 V) for current-induced magnetization switching to be obtained.

In one embodiment, a second ferromagnetic layer structure 460 (also referred to as “free layer”) is formed on or above the tunnel barrier layer structure 450. In one embodiment, the second ferromagnetic layer structure 460 may comprise at least two components of alloys of Cobalt (Co), Iron (Fe), and Nickel (Ni). In one embodiment, the second ferromagnetic layer structure 460 may be made amorphous by doping the alloys with Boron (B). In one embodiment the second ferromagnetic layer structure 460, acting as a storage layer, is not pinned and is free to rotate in the presence of a sufficient applied magnetic field.

In one embodiment, the first ferromagnetic layer structure 440 together with the tunnel barrier layer structure 450 and the second ferromagnetic layer structure 460 form a spin transfer torque magnetization reversal layer structure 490. In one embodiment, during a write operation, a vertical current applied to the device and passing through the spin transfer torque magnetization reversal layer structure 490 (i.e. through the second ferromagnetic layer structure 460, the tunnel barrier layer structure 450 and the first ferromagnetic layer structure 440) gets spin polarized and causes a torque on the magnetic polarization of the second ferromagnetic layer structure 460. In one embodiment, this torque is large enough to induce a complete reversal of the magnetization of the second ferromagnetic layer structure 460 such that the second ferromagnetic layer structure 460 functions as a storage layer to store information.

In one embodiment, a top conductive layer structure 470 is formed on or above the second ferromagnetic layer structure 460. In one embodiment, the top conducting layer structure 470 may be a multilayer formation of a Tantalum (Ta) layer and a Tantalum Nitride (TaN) layer formed on or above the Tantalum (Ta) layer. In one embodiment, the Tantalum (Ta) layer may have an approximate thickness of 2 to 10 nanometers, while the Tantalum Nitride (TaN) layer may have an approximate thickness of 5 to 10 nanometers, although these ranges should be considered approximations and reasonable variations, due for example to manufacturing, can and should be expected.

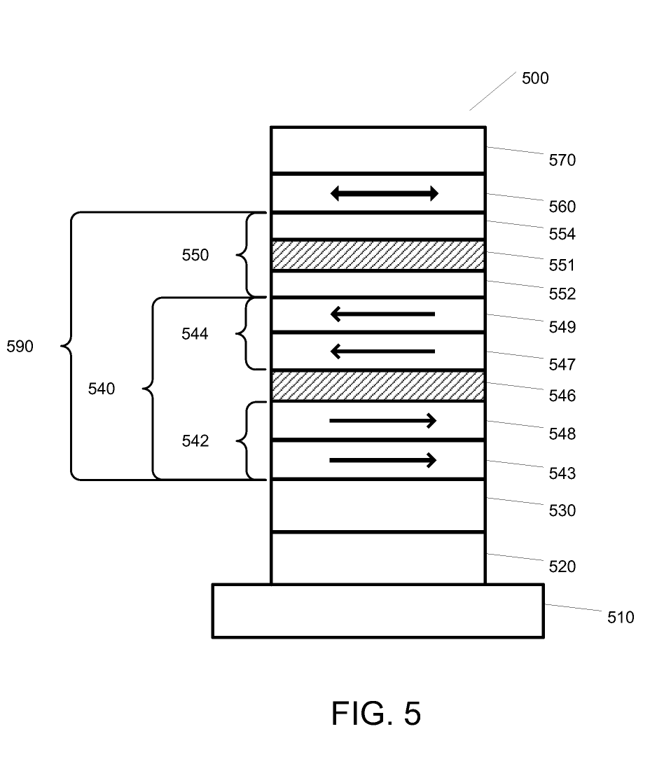

FIG. 5 is a cross-sectional view of one embodiment of a magnetic tunnel junction. In one embodiment, the magnetic tunnel junction (MTJ) stack 500 includes a carrier 510 (e.g. a substrate), followed by the formation of a bottom conducting layer structure 520 (also referred to as “bottom lead layer”) on or above the carrier 510. In one embodiment, the conducting bottom layer structure 520 may be a multilayer formation of a Tantalum Nitride (TaN) layer and a Tantalum (Ta) layer deposited by sputter processes according to the sequence TaN—Ta (Ta layer formed above or on the TaN layer). In one embodiment, the Tantalum Nitride (TaN) layer may have an approximate thickness of two to six nanometers, while the Tantalum (Ta) layer may have an approximate thickness of one to three nanometers, although these ranges should be considered approximations and reasonable variations, due for example to manufacturing, can and should be expected.

In one embodiment, a bottom pinning layer structure of antiferromagnetic material (AFM) 530 is formed on or above the bottom conducting layer structure 520. In one embodiment, the pinning layer structure of antiferromagnetic material 530 may be a Platinum Manganese (PtMn) layer. In one embodiment, the pinning layer structure of antiferromagnetic material 530 may be an Iridium Manganese (IrMn) layer.

In one embodiment, a first ferromagnetic layer structure 540, acting as a “reference layer”, is formed on or above the bottom pinning layer structure of antiferromagnetic material 530. In one embodiment, the first ferromagnetic layer structure 540 is a multilayer formation comprising a third ferromagnetic layer structure 542 disposed on or above the bottom pinning layer structure 530 of antiferromagnetic material, an antiferromagnetic coupling layer structure 546 disposed on or above the third ferromagnetic layer structure 542 and a fourth ferromagnetic layer structure 544 disposed on or above the antiferromagnetic coupling layer structure 546.

In one embodiment, the third ferromagnetic layer structure 542 is a multilayer formation comprising a fifth ferromagnetic layer structure 543 disposed on or above the bottom pinning layer structure 530 of antiferromagnetic material and a sixth ferromagnetic layer structure 548 disposed on or above the fifth ferromagnetic layer structure 543. In one embodiment, the fifth ferromagnetic layer structure 543 and the sixth ferromagnetic layer structure 548 are both pinned to the bottom pinning layer structure of antiferromagnetic material 530, in that their magnetic moments are prevented from any rotation in the presence of an external applied magnetic field up to a certain strength value. In one embodiment, the fifth ferromagnetic layer structure 543 and the sixth ferromagnetic layer structure 548 are both anti-ferromagnetically exchanged coupled to the fourth ferromagnetic layer structure 544 through the antiferromagnetic coupling layer structure 546.

In one embodiment, the fifth ferromagnetic layer structure 543 comprises at least two elements selected from the group of alloys Cobalt (Co), Iron (Fe), and Nickel (Ni). In one embodiment, the fifth ferromagnetic layer structure 543 has an approximate thickness of 1 Angstrom (Å) to 30 Angstroms (Å).

In one embodiment, the sixth ferromagnetic layer structure 548 is an amorphous magnetic layer comprising a Cobalt Iron Boron (CoFeB) layer. In one embodiment, the sixth ferromagnetic layer structure 548 of Cobalt Iron Boron (CoFeB) has an approximate atom percentage of Boron (B) of 2% to 20%. In one embodiment, the sixth ferromagnetic layer structure 548 of Cobalt Iron Boron (CoFeB) has an approximate atom percentage of Boron (B) of 8% to 13%. In one embodiment, the sixth ferromagnetic layer structure 548 of Cobalt Iron Boron (CoFeB) has an approximate atom percentage of Boron (B) of 13%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously. In one embodiment, the sixth ferromagnetic layer structure 548 has an approximate thickness of 1 Angstrom (Å) to 30 Angstroms (Å). In one embodiment, the sixth ferromagnetic layer structure 548 has an approximate thickness of 3 Angstroms (Å). These ranges, however, should be considered approximations and reasonable variations, due for example to manufacturing, can and should be expected. This method of fabricating the third ferromagnetic layer structure 542, enables high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching to be obtained.

In one embodiment, the antiferromagnetic coupling layer structure 546 comprises a Ruthenium (Ru) layer. In one embodiment, the antiferromagnetic coupling layer structure 546 has an approximate thickness of 8.1 Angstroms (Å) to 8.9 Angstroms (Å), although these ranges should be considered approximations and reasonable variations, due for example to manufacturing, can and should be expected.

In one embodiment, the fourth ferromagnetic layer structure 544 is a multilayer formation comprising a seventh ferromagnetic layer structure 547 disposed on or above the antiferromagnetic coupling layer structure 546 and an eighth ferromagnetic layer structure 549 disposed on or above the seventh ferromagnetic layer structure 547. In one embodiment, the seventh ferromagnetic layer structure 547 and the eighth ferromagnetic layer structure 549 are magnetized in parallel directions with respect to each other.

In one embodiment, the fifth ferromagnetic layer structure 543 and the sixth ferromagnetic layer structure 548 are both anti-ferromagnetically exchanged coupled to the seventh ferromagnetic layer structure 547 and the eighth ferromagnetic layer structure 549 through the antiferromagnetic coupling layer structure 546. In one embodiment, the seventh ferromagnetic layer structure 547 is an amorphous magnetic layer comprising a Cobalt Iron Boron (CoFeB) layer.

In one embodiment, the seventh ferromagnetic layer structure 547 of Cobalt Iron Boron (CoFeB) has an approximate atom percentage of Boron (B) of 2% to 30%. In one embodiment, the seventh ferromagnetic layer structure 547 of Cobalt Iron Boron (CoFeB) has an approximate atom percentage of Boron (B) of 15% to 30%. In one embodiment, the seventh ferromagnetic layer structure 547 of Cobalt Iron Boron (CoFeB) has an approximate atom percentage of Boron (B) of 25%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously. In one embodiment, the seventh ferromagnetic layer structure 547 has an approximate thickness of 1 Angstrom (Å) to 30 Angstroms (Å). In one embodiment, the seventh ferromagnetic layer structure 547 has an approximate thickness of 24 Angstroms (Å). These ranges, however, should be considered approximations and reasonable variations, due for example to manufacturing, can and should be expected.

In one embodiment, the eighth ferromagnetic layer structure 549 is an amorphous magnetic layer comprising a Cobalt Iron Boron (CoFeB) layer. In one embodiment, the eighth ferromagnetic layer structure 549 of Cobalt Iron Boron (CoFeB) has an approximate atom percentage of Boron (B) of 2% to 20%. In one embodiment, the eighth ferromagnetic layer structure 549 of Cobalt Iron Boron (CoFeB) has an approximate atom percentage of Boron (B) of 13%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously. In one embodiment, the eighth ferromagnetic layer structure 549 has an approximate thickness of 1 Angstrom (Å) to 30 Angstroms (Å). In one embodiment, the eighth ferromagnetic layer structure 549 has an approximate thickness of 3 Angstroms (Å). These ranges, however, should be considered approximations and reasonable variations, due for example to manufacturing, can and should be expected.

This method of fabricating the fourth ferromagnetic layer structure 544 it is possible to obtain high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching to be obtained.

In one embodiment, a tunnel barrier layer structure 550 is formed on or above the first ferromagnetic layer structure 540. In one embodiment, the tunnel barrier layer structure 550 is a multilayer formation comprising a first metallic layer 552, a central tunnel barrier layer 551 formed on or above the first metallic layer 552, and a second metallic layer 554 formed on or above central tunnel barrier layer 551.

In one embodiment, the first metallic 552 layer of the tunnel barrier layer structure 550 is a Magnesium (Mg) layer. In one embodiment, the first metallic layer 552 of Magnesium (Mg) has an approximate thickness of 1 to 3.9 Angstroms (Å), although these ranges should be considered approximations and reasonable variations, due for example to manufacturing, can and should be expected. In one embodiment, the first metallic layer 552 of Magnesium (Mg) has an approximate thickness of 2 Angstroms (Å). In one embodiment, the central tunnel barrier layer 551 of the tunnel barrier layer structure 550 is a Magnesium Oxide (MgO) layer. In one embodiment, the central tunnel barrier layer 551 of Magnesium Oxide (MgO) is formed by RF-sputtering from a Magnesium Oxide (MgO) target. In one embodiment, the central tunnel barrier layer 551 of Magnesium Oxide (MgO) is formed by radical oxidation of a pre-sputtered metallic layer of Magnesium (e.g. reactively depositing additional metallic Magnesium in the presence of Oxygen, in-situ radical, natural or plasma oxidation). In one embodiment, the second metallic layer 554 of the tunnel barrier layer structure 550 is a Magnesium (Mg) layer. In one embodiment, the second metallic layer 554 of Magnesium (Mg) has an approximate thickness of 1 to 3.9 Angstroms (Å), although these ranges should be considered approximations and reasonable variations, due for example to manufacturing, can and should be expected. In one embodiment, the second metallic layer 554 of Magnesium (Mg) has an approximate thickness of 2 Angstroms (Å).

In one embodiment, the first metallic 552 layer of the tunnel barrier layer structure 550 is an Aluminium (Al) layer. In one embodiment, the first metallic layer 552 of Aluminium (Al) has an approximate thickness of 1 to 3.9 Angstroms (Å), although these ranges should be considered approximations and reasonable variations, due for example to manufacturing, can and should be expected. In one embodiment, the first metallic layer 552 of Aluminium (Al) has an approximate thickness of 2 Angstroms (Å). In one embodiment, the central tunnel barrier layer 551 of the tunnel barrier layer structure 550 is an Aluminium Oxide (Al₂O₃) layer. In one embodiment, the central tunnel barrier layer 551 of Aluminium Oxide (Al₂O₃) is formed by RF-sputtering from an Aluminium Oxide (Al₂O₃) target. In one embodiment, the central tunnel barrier layer 551 of Aluminium Oxide (Al₂O₃) is formed by radical oxidation of a pre-sputtered metallic layer of Aluminium (e.g. depositing an additional metallic Aluminium layer followed by in-situ radical, natural or plasma oxidation). In one embodiment, the second metallic layer 554 of the tunnel barrier layer structure 550 is an Aluminium (Al) layer. In one embodiment, the second metallic layer 554 of Aluminium (Al) has an approximate thickness of 1 to 3.9 Angstroms (Å), although these ranges should be considered approximations and reasonable variations, due for example to manufacturing, can and should be expected. In one embodiment, the second metallic layer 554 of Aluminium (Al) has an approximate thickness of 2 Angstroms (Å). In other embodiments, this method of fabricating the tunnel barrier layer structure 550 may be extended to other materials than MgO or Al₂O₃.

In one embodiment, the introduction of the first metallic layer 552 and the second metallic layer 554 in the tunnel barrier layer structure 550 and, in particular, the use of the same material for these two metallic layers improves the bottom and top interface of the central tunnel barrier layer 551 generating a high quality tunnel barrier layer structure 550.

This method of fabricating the tunnel barrier layer structure 550 enables high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching to be obtained.

In one embodiment, a second ferromagnetic layer structure 560 (also referred to as “free layer”) is formed on or above the tunnel barrier layer structure 550. In one embodiment, the second ferromagnetic layer structure 560 may comprise at least two components of alloys of Cobalt (Co), Iron (Fe), and Nickel (Ni). In one embodiment, the second ferromagnetic layer structure 560 may be made amorphous by doping the alloys with Boron (B). In one embodiment the second ferromagnetic layer structure 560, acting as a storage layer, is not pinned and is free to rotate in the presence of a sufficient applied magnetic field.

In one embodiment, the first ferromagnetic layer structure 540 together with the tunnel barrier layer structure 550 and the second ferromagnetic layer structure 560 form a spin transfer torque magnetization reversal layer structure 590. In one embodiment, during a write operation, a vertical current applied to the device and passing through the spin transfer torque magnetization reversal layer structure 590 (i.e. through the second ferromagnetic layer structure 560, the tunnel barrier layer structure 550 and the first ferromagnetic layer structure 540) gets spin polarized and causes a torque on the magnetic polarization of the second ferromagnetic layer structure 560. In one embodiment, this torque is large enough to induce a complete reversal of the magnetization of the second ferromagnetic layer structure 560 such that the second ferromagnetic layer structure 560 functions as a storage layer to store the information.

In one embodiment, a top conductive layer structure 570 is formed on or above the second ferromagnetic layer structure 560. In one embodiment, the top conducting layer structure 570 may be a multilayer formation of a Tantalum (Ta) layer and a Tantalum Nitride (TaN) layer formed on or above the Tantalum (Ta) layer. In one embodiment, the Tantalum (Ta) layer may have an approximate thickness of 2 to 10 nanometers, while the Tantalum Nitride (TaN) layer may have an approximate thickness of 5 to 10 nanometers, although these ranges should be considered approximations and reasonable variations, due for example to manufacturing, can and should be expected.

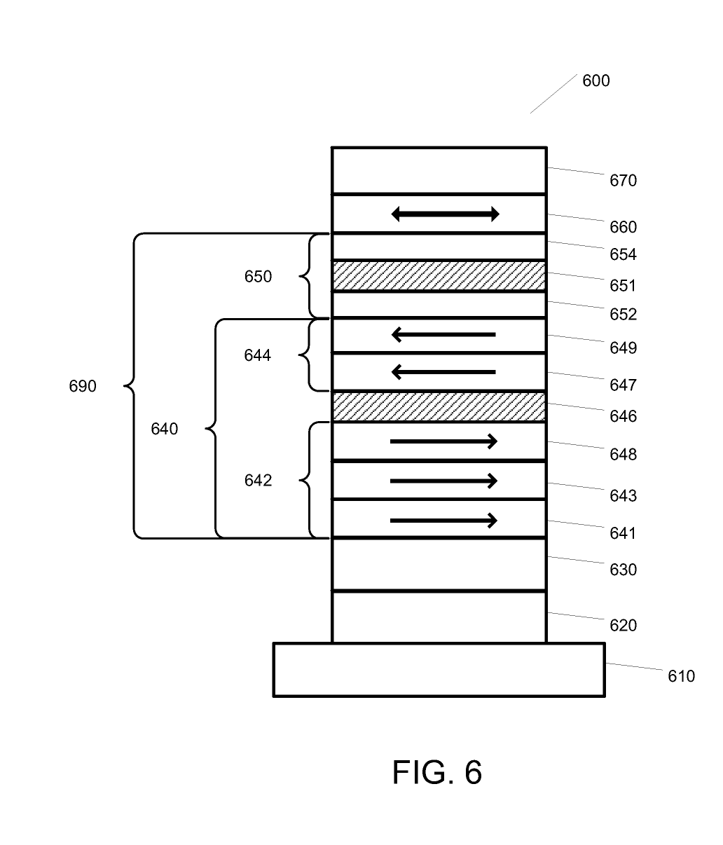

FIG. 6 is a cross-sectional view of one embodiment of a magnetic tunnel junction. In one embodiment, the magnetic tunnel junction (MTJ) stack 600 includes a carrier 610 (e.G. a substrate), followed by the formation of a bottom conducting layer structure 620 (also referred to as “bottom lead layer”) on or above the carrier 610. In one embodiment, the conducting bottom layer structure 620 may be a multilayer formation of a Tantalum Nitride (TaN) layer and a Tantalum (Ta) layer deposited by sputter processes according to the sequence TaN—Ta (Ta layer formed above or on the TaN layer). In one embodiment, the Tantalum Nitride (TaN) layer may have an approximate thickness of two to six nanometers, while the Tantalum (Ta) layer may have an approximate thickness of one to three nanometers, although these ranges should be considered approximations and reasonable variations, due for example to manufacturing, can and should be expected.

In one embodiment, a bottom pinning layer structure of antiferromagnetic material (AFM) 630 is formed on or above the bottom conducting layer structure 620. In one embodiment, the pinning layer structure of antiferromagnetic material 630 may be a Platinum Manganese (PtMn) layer. In one embodiment, the pinning layer structure of antiferromagnetic material 630 may be an Iridium Manganese (IrMn) layer.

In one embodiment, a first ferromagnetic layer structure 640, acting as a “reference layer”, is formed on or above the bottom pinning layer structure of antiferromagnetic material 630. In one embodiment, the first ferromagnetic layer structure 640 is a multilayer formation comprising a third ferromagnetic layer structure 642 disposed on or above the bottom pinning layer structure 630 of antiferromagnetic material, an antiferromagnetic coupling layer structure 646 disposed on or above the third ferromagnetic layer structure 642 and a fourth ferromagnetic layer structure 644 disposed on or above the antiferromagnetic coupling layer structure 646.

In one embodiment, the third ferromagnetic layer structure 642 is a multilayer formation comprising a ninth ferromagnetic layer structure 641 disposed on or above the bottom pinning layer structure 630 of antiferromagnetic material, a fifth ferromagnetic layer structure 643 disposed on or above the ninth ferromagnetic layer structure 641, and a sixth ferromagnetic layer structure 648 disposed on or above the fifth ferromagnetic layer structure 643. In one embodiment, the ninth ferromagnetic layer structure 641, the fifth ferromagnetic layer structure 643 and the sixth ferromagnetic layer structure 648 are all pinned to the bottom pinning layer structure of antiferromagnetic material 630, in that their magnetic moments are prevented from any rotation in the presence of an external applied magnetic field up to a certain strength value.

In one embodiment, the ninth ferromagnetic layer structure 641, the fifth ferromagnetic layer structure 643 and the sixth ferromagnetic layer structure 648 are all anti-ferromagnetically exchanged coupled to the fourth ferromagnetic layer structure 644 through the antiferromagnetic coupling layer structure 646.

In one embodiment, the ninth ferromagnetic layer structure 641 is an amorphous magnetic layer comprising a Cobalt Iron Boron (CoFeB) layer. In one embodiment, the ninth ferromagnetic layer structure 641 of Cobalt Iron Boron (CoFeB) has an approximate atom percentage of Boron (B) of 2% to 30%. In one embodiment, the ninth ferromagnetic layer structure 641 of Cobalt Iron Boron (CoFeB) has an approximate atom percentage of Boron (B) of 15% to 30%. In one embodiment, the ninth ferromagnetic layer structure 641 of Cobalt Iron Boron (CoFeB) has an approximate atom percentage of Boron (B) of 25%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously. In one embodiment, the ninth ferromagnetic layer structure 641 has an approximate thickness of 5 Angstroms (Å) to 15 Angstroms (Å). These ranges, however, should be considered approximations and reasonable variations, due for example to manufacturing, can and should be expected.

In one embodiment, the ninth ferromagnetic layer structure 641 can inhibit any Manganese (Mn) migration into the reference layer 640 and the tunnel barrier layer structure 650 when the MTJ device is annealed at 340° C. and above. In one embodiment, the ninth ferromagnetic layer structure 641 can prevent then any degradation of the MTJ device when subjected to thermal stressing.

In one embodiment, the fifth ferromagnetic layer structure 643 comprises at least two elements selected from the group of alloys Cobalt (Co), Iron (Fe), and Nickel (Ni). In one embodiment, the fifth ferromagnetic layer structure 643 has an approximate thickness of 1 Angstrom (Å) to 30 Angstroms (Å).

In one embodiment, the sixth ferromagnetic layer structure 648 is an amorphous magnetic layer comprising a Cobalt Iron Boron (CoFeB) layer. In one embodiment, the sixth ferromagnetic layer structure 648 of Cobalt Iron Boron (CoFeB) has an approximate atom percentage of Boron (B) of 2% to 20%. In one embodiment, the sixth ferromagnetic layer structure 648 of Cobalt Iron Boron (CoFeB) has an approximate atom percentage of Boron (B) of 8% to 13%. In one embodiment, the sixth ferromagnetic layer structure 648 of Cobalt Iron Boron (CoFeB) has an approximate atom percentage of Boron (B) of 13%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously. In one embodiment, the sixth ferromagnetic layer structure 648 has an approximate thickness of one Angstrom (Å) to 30 Angstroms (Å). In one embodiment, the sixth ferromagnetic layer structure 648 has an approximate thickness of 3 Angstroms (Å). These ranges, however, should be considered approximations and reasonable variations, due for example to manufacturing, can and should be expected.

This method of fabricating the third ferromagnetic layer structure 642 enables high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching to be obtained.

In one embodiment, the antiferromagnetic coupling layer structure 646 comprises a Ruthenium (Ru) layer. In one embodiment, the antiferromagnetic coupling layer structure 646 has an approximate thickness of 8.1 Angstroms (Å) to 8.9 Angstroms (Å), although these ranges should be considered approximations and reasonable variations, due for example to manufacturing, can and should be expected.

In one embodiment, the fourth ferromagnetic layer structure 644 is a multilayer formation comprising a seventh ferromagnetic layer structure 647 disposed on or above the antiferromagnetic coupling layer structure 646 and an eighth ferromagnetic layer structure 649 disposed on or above the seventh ferromagnetic layer structure 647. In one embodiment, the seventh ferromagnetic layer structure 647 and the eighth ferromagnetic layer structure 649 are magnetized in parallel directions with respect to each other. In one embodiment, the ninth ferromagnetic layer structure 641, the fifth ferromagnetic layer structure 643 and the sixth ferromagnetic layer structure 648 are all anti-ferromagnetically exchanged coupled to the seventh ferromagnetic layer structure 647 and the eighth ferromagnetic layer structure 649 through the antiferromagnetic coupling layer structure 646.

In one embodiment, the seventh ferromagnetic layer structure 647 is an amorphous magnetic layer comprising a Cobalt Iron Boron (CoFeB) layer. In one embodiment, the seventh ferromagnetic layer structure 647 of Cobalt Iron Boron (CoFeB) has an approximate atom percentage of Boron (B) of 2% to 30%. In one embodiment, the seventh ferromagnetic layer structure 647 of Cobalt Iron Boron (CoFeB) has an approximate atom percentage of Boron (B) of 15% to 30%. In one embodiment, the seventh ferromagnetic layer structure 647 of Cobalt Iron Boron (CoFeB) has an approximate atom percentage of Boron (B) of 25%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously.

In one embodiment, the seventh ferromagnetic layer structure 647 has an approximate thickness of 1 Angstrom (Å) to 30 Angstroms (Å). In one embodiment, the seventh ferromagnetic layer structure 647 has an approximate thickness of 24 Angstroms (Å). These ranges, however, should be considered approximations and reasonable variations, due for example to manufacturing, can and should be expected.

In one embodiment, the eighth ferromagnetic layer structure 649 is an amorphous magnetic layer comprising a Cobalt Iron Boron (CoFeB) layer. In one embodiment, the eighth ferromagnetic layer structure 649 of Cobalt Iron Boron (CoFeB) has an approximate atom percentage of Boron (B) of 2% to 20%. In one embodiment, the eighth ferromagnetic layer structure 649 of Cobalt Iron Boron (CoFeB) has an approximate atom percentage of Boron (B) of 13%. Such stoichiometry may be obtained either by direct deposition from a Cobalt Iron Boron (CoFeB) target with the corresponding composition or by co-sputtering from a Cobalt Iron (CoFe) and Cobalt Iron Boron (CoFeB) targets simultaneously.

In one embodiment, the eighth ferromagnetic layer structure 649 has an approximate thickness of 1 Angstrom (Å) to 30 Angstroms (Å). In one embodiment, the eighth ferromagnetic layer structure 649 has an approximate thickness of 3 Angstroms (Å). These ranges, however, should be considered approximations and reasonable variations, due for example to manufacturing, can and should be expected.

This method of fabricating the fourth ferromagnetic layer structure 644 enables high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching.

In one embodiment, a tunnel barrier layer structure 650 is formed on or above the first ferromagnetic layer structure 640. In one embodiment, the tunnel barrier layer structure 650 is a multilayer formation comprising a first metallic layer 652, a central tunnel barrier layer 651 formed on or above the first metallic layer 652, and a second metallic layer 654 formed on or above central tunnel barrier layer 651.

In one embodiment, the first metallic 652 layer of the tunnel barrier layer structure 650 is a Magnesium (Mg) layer. In one embodiment, the first metallic layer 652 of Magnesium (Mg) has an approximate thickness of 1 to 3.9 Angstroms (Å), although these ranges should be considered approximations and reasonable variations, due for example to manufacturing, can and should be expected. In one embodiment, the first metallic layer 652 of Magnesium (Mg) has an approximate thickness of 2 Angstroms (Å). In one embodiment, the central tunnel barrier layer 651 of the tunnel barrier layer structure 650 is a Magnesium Oxide (MgO) layer. In one embodiment, the central tunnel barrier layer 651 of Magnesium Oxide (MgO) is formed by RF-sputtering from a Magnesium Oxide (MgO) target. In one embodiment, the central tunnel barrier layer 651 of Magnesium Oxide (MgO) is formed by radical oxidation of a pre-sputtered metallic layer of Magnesium (e.g. reactively depositing additional metallic Magnesium in the presence of Oxygen, in-situ radical, natural or plasma oxidation). In one embodiment, the second metallic layer 654 of the tunnel barrier layer structure 650 is a Magnesium (Mg) layer. In one embodiment, the second metallic layer 654 of Magnesium (Mg) has an approximate thickness of 1 to 3.9 Angstroms (Å), although these ranges should be considered approximations and reasonable variations, due for example to manufacturing, can and should be expected. In one embodiment, the second metallic layer 654 of Magnesium (Mg) has an approximate thickness of 2 Angstroms (Å).

In one embodiment, the first metallic 652 layer of the tunnel barrier layer structure 650 is an Aluminium (Al) layer. In one embodiment, the first metallic layer 652 of Aluminium (Al) has an approximate thickness of 1 to 3.9 Angstroms (Å), although these ranges should be considered approximations and reasonable variations, due for example to manufacturing, can and should be expected. In one embodiment, the first metallic layer 652 of Aluminium (Al) has an approximate thickness of 2 Angstroms (Å). In one embodiment, the central tunnel barrier layer 651 of the tunnel barrier layer structure 650 is an Aluminium Oxide (Al₂O₃) layer. In one embodiment, the central tunnel barrier layer 651 of Aluminium Oxide (Al₂O₃) is formed by RF-sputtering from an Aluminium Oxide (Al₂O₃) target. In one embodiment, the central tunnel barrier layer 651 of Aluminium Oxide (Al₂O₃) is formed by radical oxidation of a pre-sputtered metallic layer of Aluminium (e.g. depositing an additional metallic Aluminium layer followed by in-situ radical, natural or plasma oxidation). In one embodiment, the second metallic layer 654 of the tunnel barrier layer structure 650 is an Aluminium (Al) layer. In one embodiment, the second metallic layer 654 of Aluminium (Al) has an approximate thickness of 1 to 3.9 Angstroms (Å), although these ranges should be considered approximations and reasonable variations, due for example to manufacturing, can and should be expected. In one embodiment, the second metallic layer 654 of Aluminium (Al) has an approximate thickness of 2 Angstroms (Å). In other embodiments, this method of fabricating the tunnel barrier layer structure 650 may be extended to other materials than MgO or Al₂O₃.

In one embodiment, the introduction of the first metallic layer 652 and the second metallic layer 654 in the tunnel barrier layer structure 650 and, in particular, the use of the same material for these two metallic layers improves the bottom and top interface of the central tunnel barrier layer 651 generating a high quality tunnel barrier layer structure 650.

This method of fabricating the tunnel barrier layer structure 650 enables high tunneling magnetoresistance ratios (e.g.: TMR>100%), very low resistance-area values (e.g.: RA<10 Ω-μm²), and high breakdown voltage (e.g.: V_{BD}˜0.6 V) for current-induced magnetization switching to be obtained.

In one embodiment, a second ferromagnetic layer structure 660 (also referred to as “free layer”) is formed on or above the tunnel barrier layer structure 650. In one embodiment, the second ferromagnetic layer structure 660 may comprise at least two components of alloys of Cobalt (Co), Iron (Fe), and Nickel (Ni). In one embodiment, the second ferromagnetic layer structure 660 may be made amorphous by doping the alloys with Boron (B). In one embodiment the second ferromagnetic layer structure 660, acting as a storage layer, is not pinned and is free to rotate in the presence of a sufficient applied magnetic field.

In one embodiment, the first ferromagnetic layer structure 640 together with the tunnel barrier layer structure 650 and the second ferromagnetic layer structure 660 form a spin transfer torque magnetization reversal layer structure 690. In one embodiment, during a write operation, a vertical current applied to the device and passing through the spin transfer torque magnetization reversal layer structure 690 (i.e. through the second ferromagnetic layer structure 660, the tunnel barrier layer structure 650 and the first ferromagnetic layer structure 640) gets spin polarized and causes a torque on the magnetic polarization of the second ferromagnetic layer structure 660. In one embodiment, this torque is large enough to induce a complete reversal of the magnetization of the second ferromagnetic layer structure 660 such that the second ferromagnetic layer structure 660 functions as a storage layer to store the information.

In one embodiment, a top conductive layer structure 670 is formed on or above the second ferromagnetic layer structure 660. In one embodiment, the top conducting layer structure 670 may be a multilayer formation of a Tantalum (Ta) layer and a Tantalum Nitride (TaN) layer formed on or above the Tantalum (Ta) layer. In one embodiment, the Tantalum (Ta) layer may have an approximate thickness of 2 to 10 nanometers, while the Tantalum Nitride (TaN) layer may have an approximate thickness of 5 to 10 nanometers, although these ranges should be considered approximations and reasonable variations, due for example to manufacturing, can and should be expected.

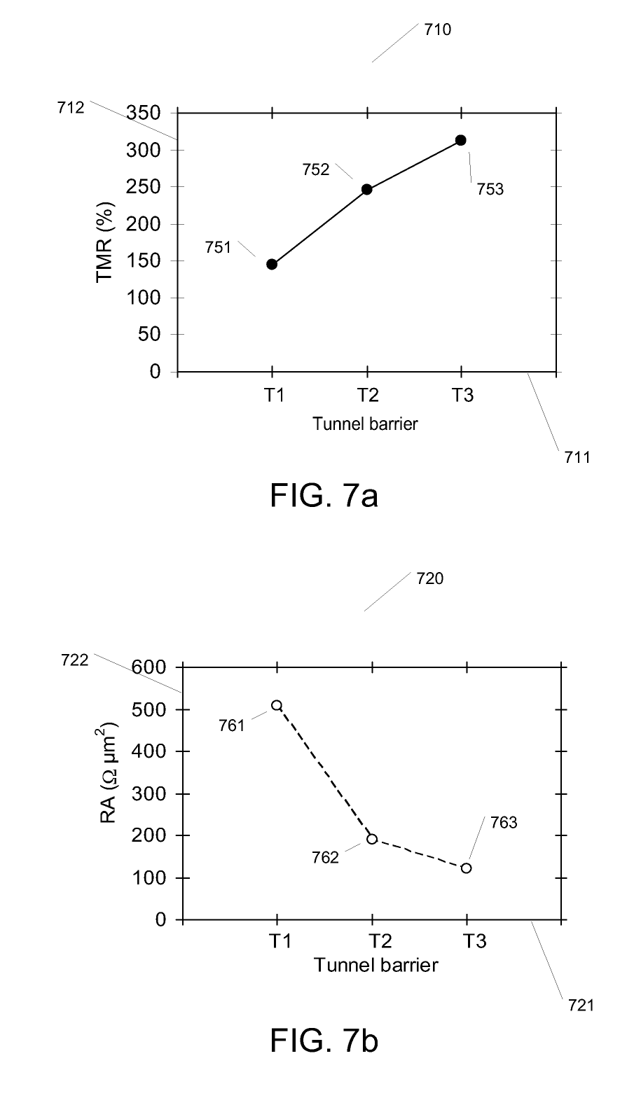

FIG. 7a is a graph 710 illustrating examples of the tunneling magnetoresistance (TMR) 712 (expressed in %) of a magnetic tunnel junction device as a function of different tunnel barrier types 711 according to different embodiments. In the example T1, a tunnel barrier layer structure comprising a Magnesium Oxide (MgO) layer having an approximate thickness of 10 Angstroms (Å) is considered, which corresponds to the tunneling magnetoresistance (TMR) value indicated in the diagram 710 as 751. In the example T2 a tunnel barrier layer structure comprising a Magnesium Oxide (MgO) layer having an approximate thickness of 10 Angstroms (Å) seeded by a Magnesium (Mg) layer having an approximate thickness of 2 Angstroms (Å) is considered, which corresponds to the tunneling magnetoresistance (TMR) value indicated in the diagram 710 as 752. In the example T3 a tunnel barrier layer structure comprising a Magnesium Oxide (MgO) layer having an approximate thickness of 10 Angstroms (Å) sandwiched between two Magnesium (Mg) layers each of them having an approximate thickness of 2 Angstroms (Å) is considered, which corresponds to the tunneling magnetoresistance (TMR) value indicated in the diagram 710 as 753.

It is clearly seen the effect generated by the two thin Magnesium (Mg) layers sandwiching the Magnesium Oxide (MgO) layer (example T3 indicated in the diagram 710 as 753): a substantial increase of about more than 76% in tunneling magnetoresistance (TMR) is obtained with the two thin Magnesium (Mg) layers sandwiching the Magnesium Oxide (MgO) layer compared to the case without the metallic Magnesium (Mg) layers. As expected the tunneling magnetoresistance (TMR) values are found to depend strongly on the quality of the tunnel barrier.

FIG. 7b is a graph 720 illustrating examples of the resistance-area values (RA) 722 (expressed in Ω-μm²) of a magnetic tunnel junction device as a function of different tunnel barrier types 721 according to different embodiments. In the example T1 a tunnel barrier layer structure comprising a Magnesium Oxide (MgO) layer having an approximate thickness of 10 Angstroms (Å) is considered, which corresponds to the resistance-area value (RA) indicated in the diagram 720 as 761. In the example T2 a tunnel barrier layer structure comprising a Magnesium Oxide (MgO) layer having an approximate thickness of 10 Angstroms (Å) seeded by a Magnesium (Mg) layer having an approximate thickness of 2 Angstroms (Å) is considered, which corresponds to the resistance-area value (RA) indicated in the diagram 720 as 762. In the example T3 a tunnel barrier layer structure comprising a Magnesium Oxide (MgO) layer having an approximate thickness of 10 Angstroms (Å) sandwiched between two Magnesium (Mg) layers each of them having an approximate thickness of 2 Angstroms (Å) is considered, which corresponds to the resistance-area value (RA) indicated in the diagram 720 as 763.

It is clearly seen the effect generated by the two thin Magnesium (Mg) layers sandwiching the Magnesium Oxide (MgO) layer (example T3 indicated in the diagram 720 as 763): a substantial decrease in resistance-area value (RA) of more than 76% is obtained with the two thin Magnesium (Mg) layers sandwiching the Magnesium Oxide (MgO) layer compared to the case without the metallic Magnesium (Mg) layers. As expected the resistance-area values (RA) are found to depend strongly on the quality of the tunnel barrier.

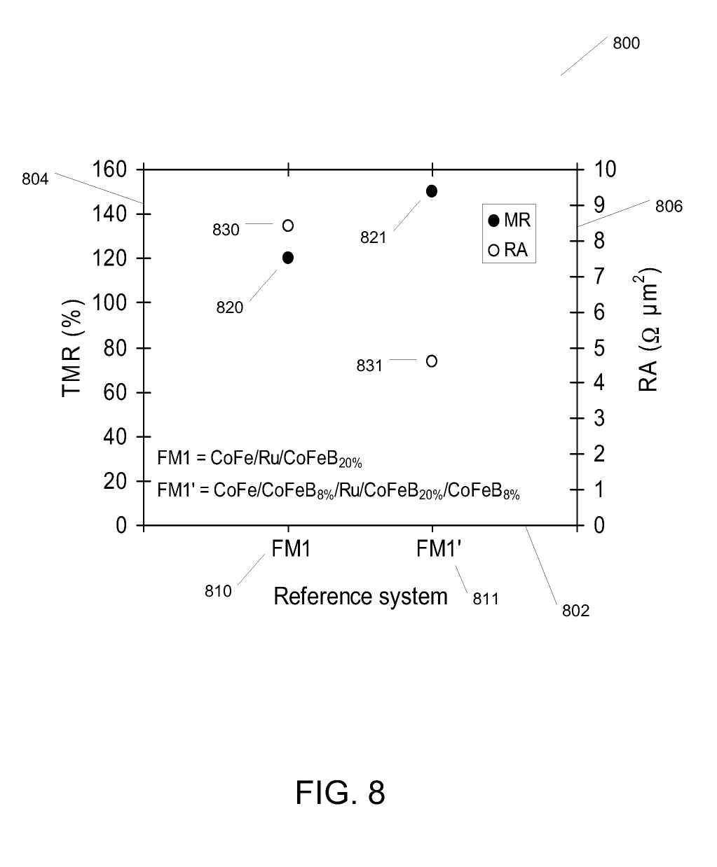

FIG. 8 is a graph 800 illustrating examples of the tunneling magnetoresistance (TMR) values 804 (expressed in %) and the resistance-area (RA) values 806 (expressed in Ω-μm²) of a magnetic tunnel junction device as a function of different reference layer structures 802 according to different embodiments. In the example FM1 810, a reference layer structure is considered, which comprises a ferromagnetic layer structure of Cobalt Iron (CoFe), an antiferromagnetic coupling layer structure of Ruthenium (Ru) disposed on or above the ferromagnetic layer structure of Cobalt Iron (CoFe), and a ferromagnetic layer structure of Cobalt Iron Boron (CoFeB) having an approximate atom percentage of Boron (B) of 20% disposed on or above the antiferromagnetic coupling layer structure of Ruthenium (Ru). The tunneling magnetoresistance (TMR) and the resistance-area (RA) values corresponding to the example FM1 810 are indicated in the diagram 800 as 820 and 830 respectively.

In the example FM1′ 811, a reference layer structure is considered, which comprises a ferromagnetic layer structure of Cobalt Iron (CoFe), a ferromagnetic layer structure of Cobalt Iron Boron (CoFeB) having an approximate atom percentage of Boron (B) of 8% disposed on or above the ferromagnetic layer structure of Cobalt Iron (CoFe), an antiferromagnetic coupling layer structure of Ruthenium (Ru) disposed on or above the ferromagnetic layer structure of Cobalt Iron Boron (CoFeB) having an approximate atom percentage of Boron (B) of 8%, a ferromagnetic layer structure of Cobalt Iron Boron (CoFeB) having an approximate atom percentage of Boron (B) of 20% disposed on or above the antiferromagnetic coupling layer structure of Ruthenium (Ru), and a ferromagnetic layer structure of Cobalt Iron Boron (CoFeB) having an approximate atom percentage of Boron (B) of 8% disposed on or above the ferromagnetic layer structure of Cobalt Iron Boron (CoFeB) having an approximate atom percentage of Boron (B) of 20%. The tunneling magnetoresistance (TMR) and the resistance-area (RA) values corresponding to the example FM1′ 811 are indicated in the diagram 800 as 821 and 831 respectively.

In the example FM1′ 811, the effect of the amorphous magnetic layers in the reference system on the tunneling magnetoresistance (TMR) and the resistance-area (RA) values should be noticed: very low resistance-area (RA) values of about 4 Ω-μm² at about 150% tunneling magnetoresistance (TMR) are obtained.

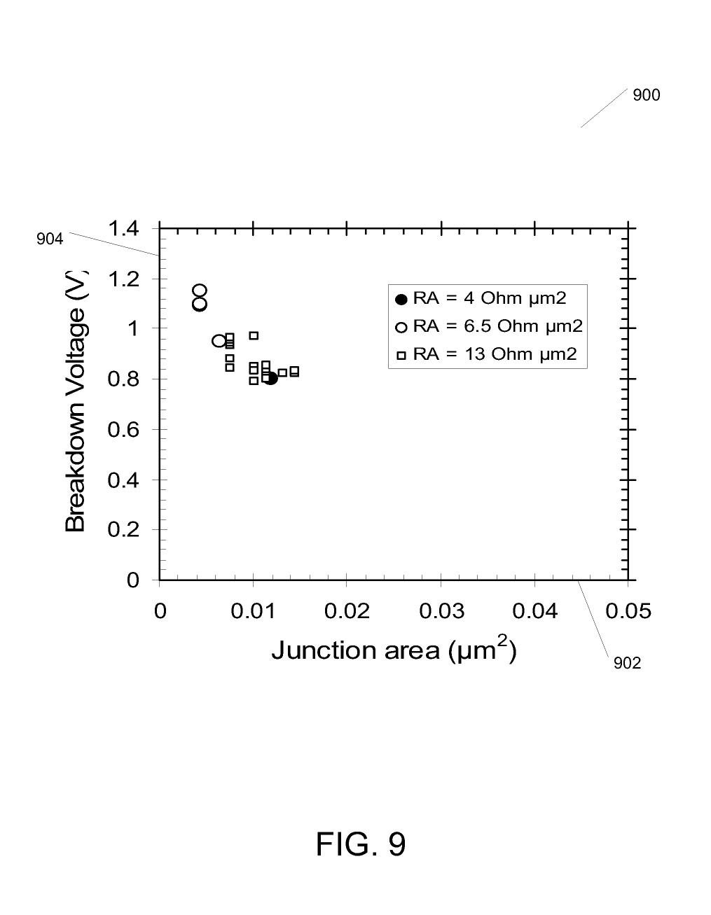

FIG. 9 is a graph 900 illustrating examples of the breakdown voltage values 904 (expressed in Volts) of a magnetic tunnel junction device as a function of different area junctions 902 (expressed in μm²) for different resistance-area (RA) values (expressed in Ω-μm²) according to different embodiments. The high breakdown voltage obtained for high quality tunnel barriers should be noticed.

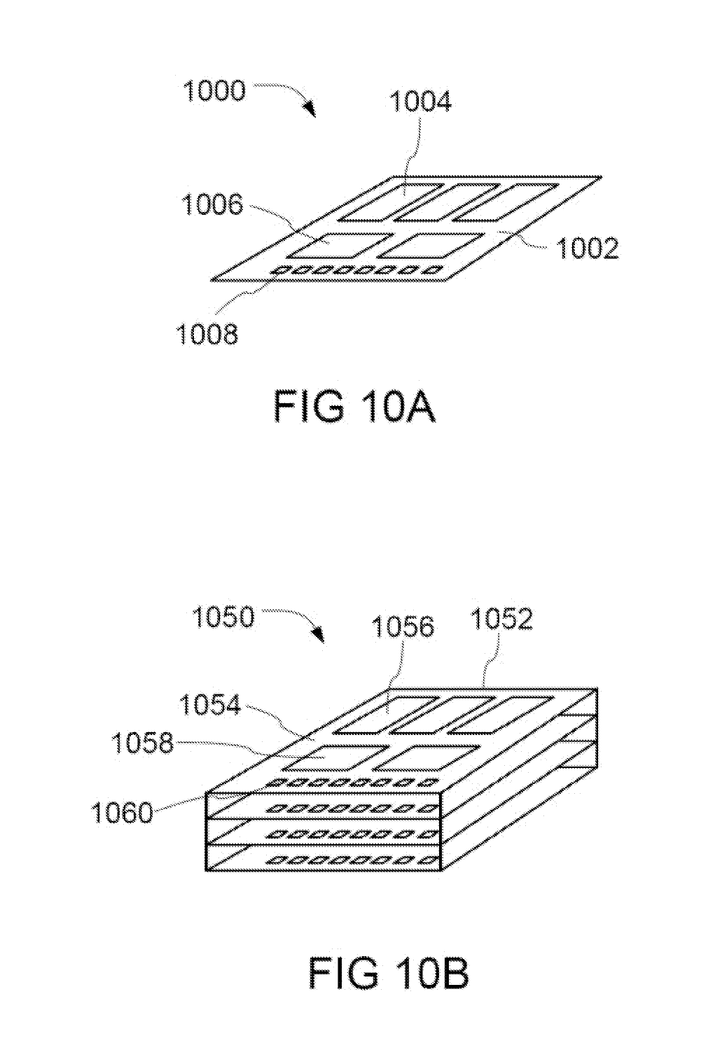

FIGS. 10A and 10B illustrate memory devices comprising embodiments of magnetic tunnel junctions, such as those described above. FIG. 10A illustrates memory module 1000, on which one or more memory devices 1004 are arranged on a substrate 1002. The memory device 1004 may include numerous memory cells, each of which uses a memory element in accordance with an embodiment of the invention (e.g. including the magnetic tunnel junction 600). The memory module 1000 may also include one or more electronic devices 1006, which may include memory, processing circuitry, control circuitry, addressing circuitry, bus interconnection circuitry, or other circuitry or electronic devices that may be combined on a module with a memory device, such as the memory device 1004. Additionally, the memory module 1000 includes multiple electrical connections 1008, which may be used to connect the memory module 1000 to other electronic components, including other modules.

In one embodiment, as illustrated by FIG. 10B, memory modules such as memory module 1000, are stacked, to form a stack 1050. For example, a stackable memory module 1052 may contain one or more memory devices 1056, arranged on a stackable substrate 1054. The memory device 1056 contains memory cells that employ memory elements in accordance with an embodiment of the invention. The stackable memory module 1052 may also include one or more electronic devices 1058, which may include memory, processing circuitry, control circuitry, addressing circuitry, bus interconnection circuitry, or other circuitry or electronic devices that may be combined on a module with a memory device, such as the memory device 1056. Electrical connections 1060 are used to connect the stackable memory module 1052 with other modules in the stack 1050, or with other electronic devices. Other modules in the stack 1050 may include additional stackable memory modules, similar to the stackable memory module 1052 described above, or other types of stackable modules, such as stackable processing modules, control modules, communication modules, or other modules containing electronic components.

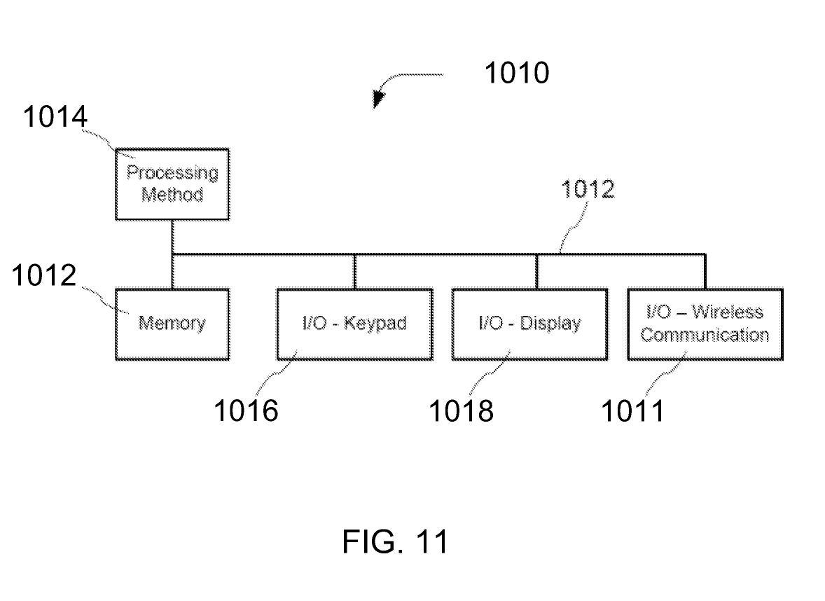

In accordance with some embodiments, memory devices that include memory elements as described herein may be used in a variety of other applications or systems, such as the illustrative computing system shown in FIG. 11. The computing system 1010 includes a memory device 1012, which may include memory elements comprising magnetic tunnel junctions in accordance with an embodiment of the invention (e.g. including the magnetic tunnel junction 600). The system also includes processing method 1014, such as a microprocessor or other processing device or controller, and one or more input/output functionalities or devices, such as a keypad 1016, display 1018, and wireless communication method 1011. The memory device 1012, processing method 1014, keypad 1016, display 1018 and wireless communication device 1011 are interconnected by a bus 1012.

The wireless communication method 1011 may have the ability to send and/or receive transmissions over a cellular telephone network, a WiFi wireless network, or other wireless communication network. It will be understood that the input/output devices, functionalities, and/or methods shown in FIG. 11 are merely examples. Memory devices including memory cells comprising magnetic tunnel junctions in accordance with embodiments described herein may be used in a variety of systems. Alternative systems may include a variety input/output devices, functionalities, and/or methods, multiple processors or processing methods, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied.

All embodiments described above can be included, for example, in magnetic read heads for hard disk drives, computers systems, notebooks, sensor systems (e.g. spin valve sensors in read heads), computer displays and cellular phones.

Additionally, the embodiments described herein are valid not only for a MTJ device, but also for a method of programming the MTJ device, for a method of forming the MTJ device, and for a MRAM array including the MTJ device.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof

What is claimed is:

1. An integrated circuit having a magnetic tunnel junction device comprising:
a spin transfer torque magnetization reversal structure comprising a first ferromagnetic structure, a second ferromagnetic structure, and a tunnel barrier structure between the first ferromagnetic structure and the second ferromagnetic structure.

2. The integrated circuit of claim 2, comprising where a current passing through the spin transfer torque magnetization reversal structure is configured to be spin polarized and causes a torque on a magnetic polarization of the second ferromagnetic layer structure.

3. The integrated circuit of claim 1, wherein the first ferromagnetic layer structure is pinned to a bottom pinning structure of antiferromagnetic material.

4. The integrated circuit of claim 1, wherein the second ferromagnetic structure is free to rotate in the presence of an applied magnetic field.

5. The integrated circuit of claim 1, wherein a magnetization direction of the second ferromagnetic structure is changed by an applied current passing through the second ferromagnetic structure, through the tunnel barrier structure and through the first ferromagnetic structure.

6. The integrated circuit of claim 1, wherein the tunnel barrier structure comprises:
a first metallic layer;
a central tunnel barrier layer disposed above the first metallic layer; and
a second metallic layer disposed above central tunnel barrier layer.

7. An integrated circuit having a magnetic tunnel junction device comprising:
a carrier;
a bottom conductive layer structure disposed above the carrier;
a bottom pinning layer structure of antiferromagnetic material disposed above the bottom conducting layer structure;
a first ferromagnetic layer structure disposed above the bottom pinning layer structure of antiferromagnetic material;
a tunnel barrier layer structure disposed above the first ferromagnetic layer structure;
a second ferromagnetic layer structure disposed above the tunnel barrier layer structure; and
a top conductive layer structure disposed above the second ferromagnetic layer structure.

8. The integrated circuit of claim 7, wherein the bottom conductive layer structure comprises:
a Tantalum Nitride (TaN) layer; and
a Tantalum (Ta) layer disposed above the Tantalum Nitride (TaN) layer.

9. The integrated circuit of claim 8, wherein the Tantalum Nitride (TaN) layer has an approximate thickness of 2 to 6 nanometers and the Tantalum (Ta) layer has an approximate thickness of 1 to 3 nanometers.

10. The integrated circuit of claim 7, wherein the bottom pinning layer structure comprises a layer selected from a group of layers consisting of a Platinum Manganese (PtMn) layer and an Iridium Manganese (IrMn) layer.

11. The integrated circuit of claim 7, wherein the first and second ferromagnetic layer structures each comprise at least two elements selected from the group of alloys of Cobalt (Co), Iron (Fe), and Nickel (Ni)

12. The integrated circuit of claim 11, wherein the alloys are doped with Boron (B).

13. The integrated circuit of claim 7, wherein the first ferromagnetic layer structure is pinned to the bottom pinning layer structure of antiferromagnetic material.

14. The integrated circuit of claim 7, wherein the tunnel barrier layer structure comprises a material selected from the group of materials consisting of Magnesium Oxide (MgO) and Aluminium Oxide (Al₂O₃).

15. The integrated circuit of claim 7, wherein the second ferromagnetic layer structure is free to rotate in the presence of an applied magnetic field.

16. The integrated circuit of claim 7, wherein a magnetization direction of the second ferromagnetic layer structure is changed by an applied current passing through the second ferromagnetic layer structure, through the tunnel barrier layer structure and through the first ferromagnetic layer structure.

17. The integrated circuit of claim 7, wherein the top conductive layer structure comprises:
a Tantalum (Ta) layer; and
a Tantalum Nitride (TaN) layer formed above the Tantalum (Ta) layer.

18. The integrated circuit of claim 17, wherein the Tantalum (Ta) layer has an approximate thickness of 2 to 10 nanometers and the Tantalum Nitride (TaN) layer has an approximate thickness of 5 to 10 nanometers.

19. The integrated circuit of claim 7, wherein the tunnel barrier layer structure comprises:
a first metallic layer;
a central tunnel barrier layer disposed above the first metallic layer; and
a second metallic layer disposed above central tunnel barrier layer.

20. The integrated circuit of claim 19, wherein the first metallic layer of the tunnel barrier layer structure comprises a Magnesium (Mg) layer.

21. The integrated circuit of claim 20, wherein the first metallic layer of Magnesium (Mg) has an approximate thickness of 1 to 3.9 Angstroms (Å).

22. The integrated circuit of claim 19, wherein the central tunnel barrier layer of the tunnel barrier layer structure comprises a Magnesium Oxide (MgO) layer.

23. The integrated circuit of claim 19, wherein the second metallic layer of the tunnel barrier layer structure comprises a Magnesium (Mg) layer.

24. The integrated circuit of claim 23, wherein the second metallic layer of Magnesium (Mg) has an approximate thickness of 1 to 3.9 Angstroms (Å).

25. The integrated circuit of claim 19, wherein the first metallic layer of the tunnel barrier layer structure comprises an Aluminium (Al) layer.

26. The integrated circuit of claim 25, wherein the first metallic layer of Aluminium (Al) has an approximate thickness of 1 to 3.9 Angstroms (Å).

27. The integrated circuit of claim 19, wherein the central tunnel barrier layer of the tunnel barrier layer structure comprises an Aluminium Oxide (Al₂O₃) layer.

28. The integrated circuit of claim 19, wherein the second metallic layer of the tunnel barrier layer structure comprises an Aluminium (Al) layer.

29. The integrated circuit of claim 16, wherein the second metallic layer of Aluminium (Al) has an approximate thickness of 1 to 3.9 Angstroms (Å).

30. The integrated circuit of claim 7, wherein the first ferromagnetic layer structure comprises:
a third ferromagnetic layer structure disposed above the bottom pinning layer structure of antiferromagnetic material;
an antiferromagnetic coupling layer structure disposed above the third ferromagnetic layer structure; and
a fourth ferromagnetic layer structure disposed above the coupling layer structure.

31. The integrated circuit of claim 30, wherein the third ferromagnetic layer structure is pinned to the bottom pinning layer structure of antiferromagnetic material.

32. The integrated circuit of claim 30, wherein the third ferromagnetic layer structure and the fourth ferromagnetic layer structure are magnetized in antiparallel directions with respect to each other through the antiferromagnetic coupling layer structure.

33. The integrated circuit of claim 30, wherein the third and fourth ferromagnetic layer structures each comprise at least two elements selected from the group of alloys of Cobalt (Co), Iron (Fe), and Nickel (Ni)

34. The integrated circuit of claim 33, wherein the alloys are doped with Boron (B).

35. The integrated circuit of claim 30, wherein the antiferromagnetic coupling layer structure comprises a Ruthenium (Ru) layer.

36. The integrated circuit of claim 30, wherein the antiferromagnetic coupling layer structure has an approximate thickness of 8.1 Angstroms (Å) to 8.9 Angstroms (Å).

37. The integrated circuit of claim 30, wherein the third ferromagnetic layer structure comprises:
a fifth ferromagnetic layer structure disposed above the bottom pinning layer structure of antiferromagnetic material; and
a sixth ferromagnetic layer structure disposed above the fifth ferromagnetic layer structure.

38. The integrated circuit of claim 37, wherein the fifth ferromagnetic layer structure and the sixth ferromagnetic layer structure are both pinned to the bottom pinning layer structure of antiferromagnetic material.

39. The integrated circuit of claim 37, wherein the fifth ferromagnetic layer structure and the sixth ferromagnetic layer structure are both anti-ferromagnetically exchanged coupled to the fourth ferromagnetic layer structure through the antiferromagnetic coupling layer structure.

40. The integrated circuit of claim 37, wherein the fifth ferromagnetic layer structure comprises at least two elements selected from the group of alloys Cobalt (Co), Iron (Fe), and Nickel (Ni).

41. The integrated circuit of claim 37, wherein the fifth ferromagnetic layer structure has an approximate thickness of 1 Angstrom (Å) to 30 Angstroms (Å).

42. The integrated circuit of claim 37, wherein the sixth ferromagnetic layer structure comprises a Cobalt Iron Boron (CoFeB) layer.

43. The integrated circuit of claim 42, wherein the sixth ferromagnetic layer structure of Cobalt Iron Boron (CoFeB) has an approximate atom percentage of Boron (B) of 2% to 20%.

44. The integrated circuit of claim 37, wherein the sixth ferromagnetic layer structure has an approximate thickness of 1 Angstrom (Å) to 30 Angstroms (Å).

45. The integrated circuit of claim 30, wherein the fourth ferromagnetic layer structure comprises:
a seventh ferromagnetic layer structure disposed above the antiferromagnetic coupling layer structure; and
an eighth ferromagnetic layer structure disposed above the seventh ferromagnetic layer structure.

46. The integrated circuit of claim 45, wherein the seventh ferromagnetic layer structure and the eighth ferromagnetic layer structure are magnetized in parallel directions with respect to each other.

47. The integrated circuit of claim 45, wherein the seventh ferromagnetic layer structure comprises an amorphous magnetic layer comprising a Cobalt Iron Boron (CoFeB) layer.

48. The integrated circuit of claim 47, wherein the seventh ferromagnetic layer structure of Cobalt Iron Boron (CoFeB) has an approximate atom percentage of Boron (B) of 2% to 30%.

49. The integrated circuit of claim 45, wherein the seventh ferromagnetic layer structure has an approximate thickness of 1 Angstrom (Å) to 30 Angstroms (Å).

50. The integrated circuit of claim 45, wherein the eighth ferromagnetic layer structure comprises an amorphous magnetic layer comprising a Cobalt Iron Boron (CoFeB) layer.

51. The integrated circuit of claim 50, wherein the eighth ferromagnetic layer structure of Cobalt Iron Boron (CoFeB) has an approximate atom percentage of Boron (B) of 2% to 20%.

52. The integrated circuit of claim 45, wherein the eighth ferromagnetic layer structure has an approximate thickness of 1 Angstrom (Å) to 30 Angstroms (Å).

53. The integrated circuit of claim 30, wherein the third ferromagnetic layer structure comprises:
a ninth ferromagnetic layer structure disposed above the bottom pinning layer structure of antiferromagnetic material;
a fifth ferromagnetic layer structure disposed above the ninth ferromagnetic layer structure; and
a sixth ferromagnetic layer structure disposed above the fifth ferromagnetic layer structure.

54. The integrated circuit of claim 53, wherein the ninth ferromagnetic layer structure, the fifth ferromagnetic layer structure, and the sixth ferromagnetic layer structure are all pinned to the bottom pinning layer structure of antiferromagnetic material.

55. The integrated circuit of claim 53, wherein the ninth ferromagnetic layer structure, the fifth ferromagnetic layer structure, and the sixth ferromagnetic layer structure are all anti-ferromagnetically exchanged coupled to the fourth ferromagnetic layer structure through the antiferromagnetic coupling layer structure.

56. The integrated circuit of claim 53, wherein the ninth ferromagnetic layer structure comprises an amorphous magnetic layer comprising a Cobalt Iron Boron (CoFeB) layer.

57. The integrated circuit of claim 56, wherein the ninth ferromagnetic layer structure of Cobalt Iron Boron (CoFeB) has an approximate atom percentage of Boron (B) of 2% to 30%.

58. The integrated circuit of claim 53, wherein the ninth ferromagnetic layer structure has an approximate thickness of 5 Angstroms (Å) to 15 Angstroms (Å).

59. A method of forming an integrated circuit having a magnetic tunnel junction device comprising:
providing a carrier;
forming a bottom conductive layer structure above the carrier;
forming a bottom pinning layer structure of antiferromagnetic material above the bottom conducting layer structure;
forming a first ferromagnetic layer structure above the bottom pinning layer structure of antiferromagnetic material;
forming a tunnel barrier layer structure above the first ferromagnetic layer structure;
forming a second ferromagnetic layer structure above the tunnel barrier layer structure; and
forming a top conductive layer structure above the second ferromagnetic layer structure.

60. An array of magnetic random access memory structures, each of the magnetic memory structures comprising:
a integrated circuit comprising:
a carrier;
a bottom conductive layer structure disposed above the carrier;
a bottom pinning layer structure of antiferromagnetic material disposed above the bottom conducting layer structure;
a first ferromagnetic layer structure disposed above the bottom pinning layer structure of antiferromagnetic material;
a tunnel barrier layer structure disposed above the first ferromagnetic layer structure;
a second ferromagnetic layer structure disposed above the tunnel barrier layer structure; and
a top conductive layer structure disposed above the second ferromagnetic layer structure; and
a write conductor contacting and selecting the magnetic tunnel junction device, the write conductor configured to apply a current to the magnetic tunnel junction device which passes through the second ferromagnetic layer structure, the tunnel barrier layer structure and the first ferromagnetic layer structure, wherein the current is spins polarized and causes a torque on the magnetic polarization of the second ferromagnetic layer structure, wherein the torque induces a complete reversal of a magnetization of the second ferromagnetic layer structure.

61. A magnetic read head device comprising:
a integrated circuit comprising:
a carrier;
a bottom conductive layer structure disposed above the carrier;
a bottom pinning layer structure of antiferromagnetic material disposed above the bottom conducting layer structure;
a first ferromagnetic layer structure disposed above the bottom pinning layer structure of antiferromagnetic material;
a tunnel barrier layer structure disposed above the first ferromagnetic layer structure;
a second ferromagnetic layer structure disposed above the tunnel barrier layer structure; and
a top conductive layer structure disposed above the second ferromagnetic layer structure.

62. A computing system comprising:
an input apparatus;
an output apparatus;
a processing apparatus; and
a memory element, the memory element comprising:
a integrated circuit comprising:
a carrier;
a bottom conductive layer structure disposed above the carrier;
a bottom pinning layer structure of antiferromagnetic material disposed above the bottom conducting layer structure;
a first ferromagnetic layer structure disposed above the bottom pinning layer structure of antiferromagnetic material;
a tunnel barrier layer structure disposed above the first ferromagnetic layer structure;
a second ferromagnetic layer structure disposed above the tunnel barrier layer structure; and
a top conductive layer structure disposed above the second ferromagnetic layer structure.

63. The computing system of claim 62, wherein at least one of the input apparatus and the output apparatus comprises a wireless communication apparatus.

64. A memory module having a integrated circuit comprising:
a carrier;
a bottom conductive layer structure disposed above the carrier;
a bottom pinning layer structure of antiferromagnetic material disposed above the bottom conducting layer structure;
a first ferromagnetic layer structure disposed above the bottom pinning layer structure of antiferromagnetic material;
a tunnel barrier layer structure disposed above the first ferromagnetic layer structure;
a second ferromagnetic layer structure disposed above the tunnel barrier layer structure;
a top conductive layer structure disposed above the second ferromagnetic layer structure.

65. The memory module of claim 64, wherein the memory module is stackable.

66. A sensor system comprising:
a integrated circuit including:
a carrier;
a bottom conductive layer structure disposed above the carrier;
a bottom pinning layer structure of antiferromagnetic material disposed above the bottom conducting layer structure;
a first ferromagnetic layer structure disposed above the bottom pinning layer structure of antiferromagnetic material;
a tunnel barrier layer structure disposed above the first ferromagnetic layer structure;
a second ferromagnetic layer structure disposed above the tunnel barrier layer structure; and
a top conductive layer structure disposed above the second ferromagnetic layer structure.
